(19) United States
(12) Patent Application Publication
(10) Pub. No.: US 2026/0332461 A1
(43) Pub. Date: Oct. 22, 2026

(54) TRANSMITTER AND RECEIVER FOR 3-LEVEL PULSE AMPLITUDE MODULATION SIGNALING AND SYSTEM INCLUDING THE SAME

(71) Applicant: Samsung Electronics Co., Ltd., Suwon-si (KR)

(72) Inventors: Kwanseo Park, Seoul (KR); Dongwoo Kang, Seoul (KR); Junsoo Park, Seoul (KR)

(73) Assignee: UIF (University Industry Foundation), Yonsei University, Seoul (KR)

(21) Appl. No.: 19/355,613

(22) Filed: Oct. 10, 2025

(30) Foreign Application Priority Data
Apr. 17, 2025 (KR) 10-2025-0050347

(51) Int. Cl. H04L 25/49; H04L 25/03

(52) U.S. Cl. CPC H04L 25/4917; H04L 25/03006; H04L 2025/03363

(57) ABSTRACT

A transmitter includes a first encoder, a second encoder, a serializer and a driver. The first encoder pseudo random binary sequences to multi-level data and each level in the multi-level data indicating one voltage level of a plurality of voltage levels. The second encoder groups the multi-level data into a K-bit code and encode the K-bit code into (K+1)-bit code based on a mapping table. A difference in values between any two consecutive bits of the (K+1)-bit code is less than a difference between highest and lowest values that each bit in the (K+1)-bit code can have. The serializer generates a first serial data and a second serial data based on the (K+1)-bit code. The driver generates an output data signal based on the first serial data, the second serial data, a pull-up control code, and a pull-down control code and transmits the output data signal through a channel.

### CROSS-REFERENCE TO RELATED APPLICATION

This application claims priority under 35 USC § 119 to Korean Patent Application No. 10-2025-0050347, filed on Apr. 17, 2025, in the Korean Intellectual Property Office (KIPO), the disclosure of which is incorporated herein by reference in its entirety.

### BACKGROUND

Recently, an intensive requirement of memory bandwidth for high performance computing (HPC), such as an artificial intelligence (AI) and a graphic processing unit (GPU) gets attracting. The enlargement of the bandwidth may rely on the innovation of the process technology. Development in the process technology has been creating higher density in integrated circuits (ICs).

For increasing the bandwidth, pulse amplitude modulation-2 (PAM-2) signaling having two data modulation levels may be used for data communication. The conventional PAM-2 signaling may make it possible to simplify the structure of a transceiver. However, only one bit may be transmitted during one unit interval (UI), and the clock frequency needs to increase to increase bandwidth. For this reason, this may cause channel attenuation and deterioration of clock quality.

Pulse amplitude modulation-4 (PAM-4) signaling may transmit two bits during one UI. However, in terms of single-ended signaling, the sensing margin of the PAM-4 signaling is very small, and the PAM-4 signaling is very sensitive to the supply voltage noise and the linearity of a signal is very low. Accordingly, the feasibility of the PAM-4 signaling may be low.

### SUMMARY

Example implementations relate generally to semiconductor integrated circuits, and more particularly to transmitter and receiver for 3-level pulse amplitude modulation signaling and system including the same.

Some example implementations provide a transmitter capable of reducing a crosstalk and a jitter while using PAM-3 signaling.

Some example implementations provide a receiver capable of reducing a crosstalk and a jitter while using PAM-3 signaling.

Some example implementations provide a system including a transmitter and a receiver that are capable of reducing a crosstalk and a jitter while using PAM-3 signaling.

According to example implementations, a transmitter includes a first encoder, a second encoder, a serializer and a driver. The first encoder encodes one or more pseudo random binary sequences to multi-level data and each level in the multi-level data indicating one voltage level of a plurality of voltage levels comprising at least a first voltage level, a second voltage level and a third voltage level. The second encoder groups the multi-level data into a K-bit code and encode the K-bit code into (K+1)-bit code based on a mapping table, a value of each bit of the (K+1)-bit code corresponds to a voltage level of the plurality of voltage levels and K is three. A difference in values between any two consecutive bits of the (K+1)-bit code is less than a difference between highest and lowest values that each bit in the (K+1)-bit code can have. The serializer generates a first serial data and a second serial data based on the (K+1)-bit code. The driver generates an output data signal based on the first serial data, the second serial data, a pull-up control code, and a pull-down control code and transmits the output data signal through a channel.

According to example implementations, a receiver includes an amplifier, a signal converter, a first comparator, a second comparator, a first decoder and a second decoder. The amplifier amplifies an input data signal into an amplified signal, wherein the input data signal comprises a first voltage level, a second voltage level and a third voltage level and the input data signal is received through a channel. The signal converter converts the amplified signal into a differential signal including a first signal and a second signal. The first comparator samples the first signal to generate a first comparison signal. The second comparator samples the second signal to generate a second comparison signal. The first decoder groups each of a first deserialized signal and a second deserialized signal into a (K+1)-bit code and generates, based on a number of consecutive identical bits of the (K+1)-bit code being equal to or smaller than K, a first decoded signal and a second decoded signal and decodes the (K+1)-bit code into K-bit code based on a mapping table. K is three. The second decoder decodes the first decoded signal and the second decoded signal to pseudo random binary sequences, based on a voltage level of each of the first decoded signal and the second decoded signal.

According to example implementations, a system includes a transmitter, a channel and a receiver. The transmitter outputs a write data to be stored in a semiconductor memory device. The channel transmits the write data. The receiver receives the write data. The transmitter groups an input data signal into a K-bit code, which has a first voltage level, a second voltage level and a third voltage level, encodes the K-bit code into (K+1)-bit code based on a mapping table and generates the write data based on the (K+1)-bit code. A difference in values between any two consecutive bits of the (K+1)-bit code is less than a difference between highest and lowest values that each bit in the (K+1)-bit code can have and K is three. The receiver converts the write data into a differential signal including a first signal and a second signal, samples the first signal and the second signal to generate a first comparison signal and a second comparison signal, respectively, groups each of a first deserialized signal and a second deserialized signal into the (K+1)-bit code, generates, in response to a number of consecutive identical bits of the (K+1)-bit code being equal to or smaller than K, a first decoded signal and a second decoded signal by decoding the grouped (K+1)-bit code into the K-bit code, and generates a data signal based on the first decoded signal and the second decoded signal.

According to example implementations, there is provided a method of operating a transmitter. According to the method, a multi-level data sequence having a first voltage level, a second voltage level and a third voltage level is received by an encoder, the multi-level data sequence is grouped into a K-bit code (K is three) by the encoder, the K-bit code is encoded to a (K+1)-bit code based on a mapping table with avoiding a maximum transition of the (K+1)-bit code by the encoder and an output data signal is generated by driving the (K+1)-bit code by an driver.

Accordingly, the transmitter according to example implementations, may reduce the crosstalk and the jitter of the output data signal on the channel by converting 3-bit code to 4-bit code with avoiding maximum transition, by performing feed-forward equalizing and by transmitting converted signal through the channel.

### BRIEF DESCRIPTION OF THE DRAWINGS

Illustrative, non-limiting example implementations will be more clearly understood from the following detailed description taken in conjunction with the accompanying drawings.

FIG. 1 is a block diagram illustrating a system including a transmitter and a receiver according to example implementations.

FIG. 2 is a block diagram illustrating a semiconductor package that may employs the transmitter and the receiver according to example implementations.

FIG. 3 is a diagram for explaining crosstalk occurring in channels of the semiconductor package of FIG. 2.

FIG. 4A is an eye diagram of a PAM-3 signal when an encoding scheme avoiding maximum transition is not used.

FIG. 4B is an eye diagram of a PAM-3 signal when an encoding scheme avoiding maximum transition is used.

FIG. 5 is a block diagram illustrating an example of the transmitter in the system of FIG. 1 according to example implementations.

FIG. 6 illustrates a mapping table that the second encoder in FIG. 2 uses according to example implementations.

FIG. 7 is a circuit diagram illustrating an example of the first pulse generator in the receiver of FIG. 5 according to example implementations.

FIG. 8 is a timing diagram illustrating an operation of the first pulse generator in FIG. 7 according to example implementations.

FIG. 9 is a circuit diagram illustrating an example of the driver in the transmitter of FIG. 5 according to example implementations.

FIG. 10 illustrates data dependent jitters when the NRZ signaling and the 3T4T coding with avoiding maximum transition are used according to PRBS patterns.

FIG. 11 is a graph illustrating data dependent jitters when the NRZ signaling and the 3T4T coding with avoiding maximum transition are used according to PRBS patterns.

FIGS. 12A and 12B are diagrams for explaining that the third encoder in FIG. 5 cancels the crosstalk generated by transition of a data on an adjacent channel, respectively.

FIGS. 13A and 13B illustrate that the third encoder in FIG. 5 adjusts a number of bits in each of the first control code and the second control code based on a number of adjacent channels, respectively.

FIG. 14 is a block diagram illustrating an example of the receiver in the system of FIG. 1 according to example implementations.

FIG. 15 is a circuit diagram illustrating an example of the amplifier in the receiver of FIG. 14 according to example implementations.

FIG. 16 is a circuit diagram illustrating an example of the signal converter in the receiver of FIG. 14 according to example implementations.

FIG. 17 is a flow chart illustrating an operation of the first decoder in FIG. 14 according to example implementations.

FIG. 18 illustrates that the first decoder in the receiver of FIG. 14 performs a self training.

FIG. 19 is a block diagram illustrating an example of the stacked memory device in FIG. 2 according to example implementations.

FIG. 20 is a block diagram illustrating an example of the first core die in the stacked memory device of FIG. 19 according to example implementations.

FIG. 21 illustrates an example of a first bank array in the first core die of FIG. 20 according to example implementations.

FIG. 22A is a flow chart illustrating an operation of a transmitter according to example implementations.

FIG. 22B is a flow chart illustrating an encoding operation of a transmitter according to example implementations.

FIG. 22C is a flow chart illustrating a decoding operation of a receiver according to example implementations.

FIG. 23 is a block diagram illustrating a memory system according to example implementations.

FIGS. 24 and 25 are block diagrams illustrating an example of a memory system of FIG. 23.

FIG. 26 is a diagram illustrating a semiconductor package including the stacked memory device according to example implementations.

### DETAILED DESCRIPTION

Various example implementations will be described more fully with reference to the accompanying drawings, in which implementations are shown. The present disclosure may, however, be embodied in many different forms and should not be construed as limited to the implementations set forth herein. Like reference numerals refer to like elements throughout this application.

A multi-level signaling scheme may be used as a means of compressing the bandwidth required to transmit data at a given bit rate. In a simple binary scheme, two single symbols, usually two voltage levels, may be used to represent ‘1’ and ‘0,’ and thus the symbol rate may be equal to the bit rate. In contrast, the principle of the multi-level signaling scheme may be to use a larger alphabet of m symbols to represent data, so that each symbol may represent more than one bit of data. As a result, the number of symbols that needs to be transmitted may be less than the number of bits (e.g., the symbol rate may be less than the bit rate), and thus the bandwidth may be compressed.

In other words, the multi-level signaling scheme may be used to increase a data transmission (or transfer) rate without increasing the frequency of data transmission and/or a transmission power of the communicated data. An example of one type of the multi-level signaling scheme may be a pulse amplitude modulation (PAM) scheme, where a unique symbol of a multi-level signaling may represent a plurality of bits of data.

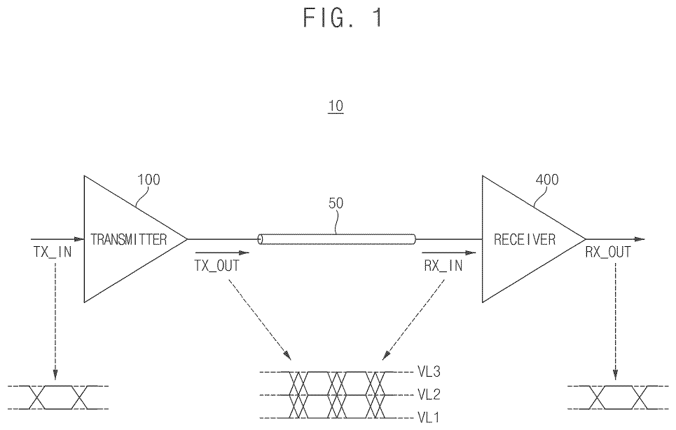

FIG. 1 is a block diagram illustrating a system including a transmitter and a receiver according to example implementations.

Referring to FIG. 1, a system 10 may include a transmitter (TX) 100 and a receiver (RX) 400 and the transmitter 100 and the receiver 400 may be connected to each other through a channel 50.

The transmitter 100 may generate an output data signal TX_OUT based on an input data signal TX_IN including a plurality of binary input bits. The output data signal TX_OUT may include a plurality of PAM-3 symbols and each of the plurality of PAM-3 symbols may have a first voltage level VL1, a second voltage level VL2 and a third voltage level VL3. The output data signal TX_OUT may be transmitted to the receiver 400 through the channel 50. The receiver 400 may generate an output data signal RX_OUT including a plurality of binary output bits based on an input data signal RX_IN including a plurality of PAM-3 symbols.

For example, the three voltage levels of the output data signal TX_OUT may include a first voltage level VL1, a second voltage level VL2 higher than the first voltage level VL1, and a third voltage level VL3 higher than the second voltage level VL2. The transmitter 100 may generate the output data signal TX_OUT with avoiding a transition from the first voltage level VL1 to the third voltage level VL3 and a transition from the third voltage level VL3 to the first voltage level VL1 and thus, may reduce crosstalk and jitter. The first voltage level VL1, the second voltage level VL2 and the third voltage level VL3 may be referred to as a low level, a middle (or mid) level and a high level, respectively.

For example, the output data signal RX_OUT may have two voltage levels that are different from each other, and one value (or data) included in the output data signal RX_OUT that is the binary signal may represent one value (or bit) included in the input data signal TX_IN.

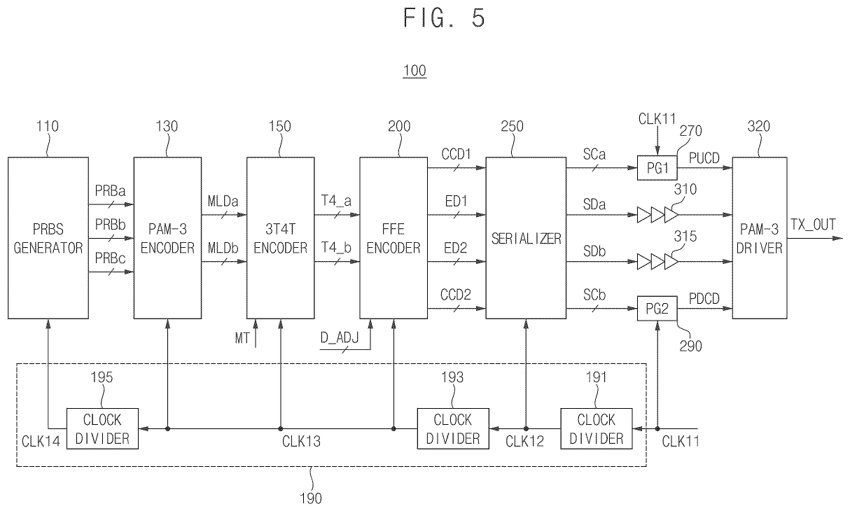

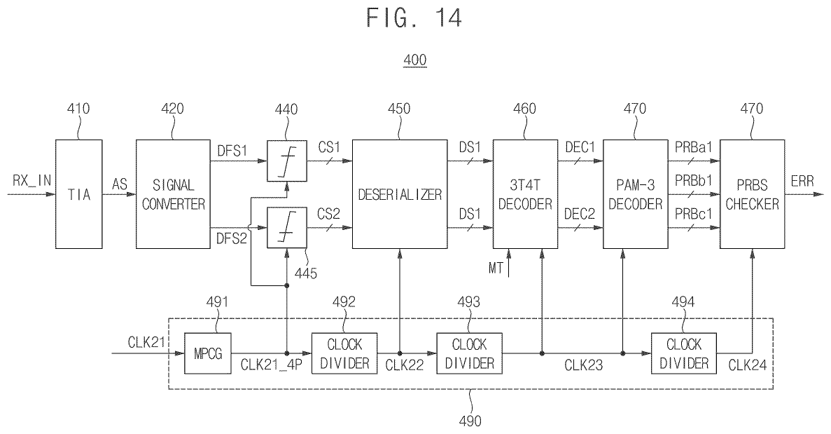

The transmitter 100 and the receiver 400 according to example implementations may have a structure for reducing occupied area, the crosstalk and the jitter. Detailed configurations and operations of the transmitter 100 will be described with reference to FIGS. 5 through 13. Detailed configurations and operations of the receiver 400 will be described with reference to FIGS. 14 through 18.

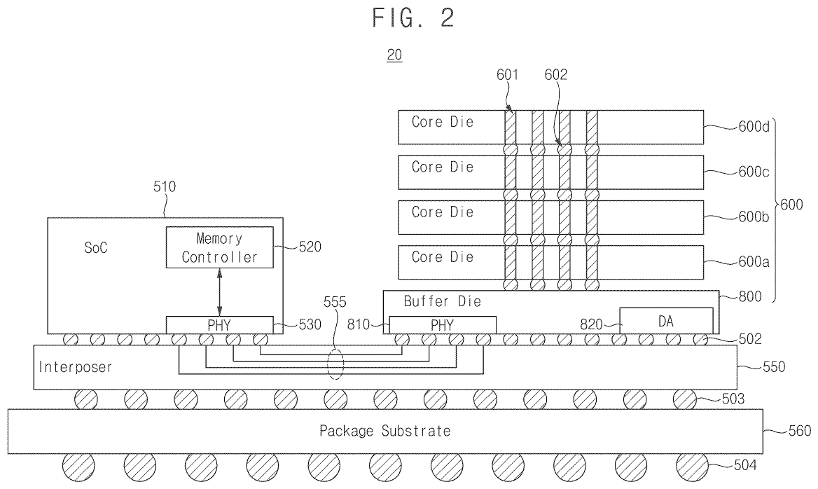

FIG. 2 is a block diagram illustrating a semiconductor package that may employs the transmitter and the receiver according to example implementations.

Referring to FIG. 2, a semiconductor package 500 may include a stacked memory device 600, a system on chip SoC 510, an interposer 550, and a package substrate 560. The stacked memory device 600 may include a buffer die 800 and core dies 600a, 600b, 600c and 600d.

Each of the core dies 600a, 600b, 600c and 600d may include a memory cell array. The buffer die 800 may include a physical region PHY 810 and a direct access region DA 820. The physical region 810 may be electrically connected with a physical region PHY 530 of the system on chip 510. Through the physical region 810, the stacked memory device 600 may receive signals from the system on chip 510 or may transmit signals to the system on chip 510.

The direct access region 820 may provide an access path capable of testing the stacked memory device 600 without passing through the system on chip 510. The direct access region 820 may include a conduction means (e.g., a port or a pin) capable of directly communicating with an external test device. A test signal and data received through the direct access region 820 may be transmitted to the core dies 600a, 600b, 600c and 600d through TSVs. To test the core dies 600a, 600b, 600c and 600d, data read from the core dies 600a, 600b, 600c and 600d may be transmitted to the test device through the TSVs and the direct access region 820. As such, a direct access test may be performed with respect to the core dies 600a, 600b, 600c and 600d.

The buffer die 800 and the core dies 600a, 600b, 600c and 600d may be electrically connected through TSV 601 and bumps 602. The buffer die 800 may receive signals, which are provided to each channel through the bumps 602 allocated for each channel, from the system on chip 510. For example, the bumps 602 may be micro-bumps.

The system on chip 510 may execute applications that the semiconductor package 500 supports, by using the stacked memory device 600. For example, the system on chip 510 may include at least one of a central processing unit (CPU), an application processor (AP), a graphic processing unit (GPU), a neural processing unit (NPU), a tensor processing unit (TPU), a vision processing unit (VPU), an image signal processor (ISP), or a digital signal processor (DSP) and may execute specialized calculations.

The system on chip 510 may include the physical region 530 and a memory controller 520. The physical region (i.e. a physical layer) 530 may include input/output circuits for exchanging signals with the physical region 810 of the stacked memory device 600. The system on chip 510 may provide various signals to the physical region 810 through the physical region 530. The signals provided to the physical region 810 may be transferred to the core dies 600a, 600b, 600c and 600d through the interface circuits of the physical region 810 and the TSVs 601. Each of the physical region 530 and the physical region 810 may include a transmitter and a receiver. The transmitter may employ the transmitter 100 and the receiver may employ the receiver 400.

The memory controller 520 may control overall operations of the stacked memory device 600. The memory controller 520 may provide the stacked memory device 600 with signals for controlling the stacked memory device 600, through the physical region 530.

The interposer 550 may connect the stacked memory device 600 and the system on chip 510. The interposer 550 may connect the physical region 810 of the stacked memory device 600 and the physical region 530 of the system on chip 510 and may provide physical paths 555 formed by using conductive materials. As such, the stacked memory device 600 and the system on chip 510 may be stacked on the interposer 550 and may exchange signals with each other. The physical paths 555 may be referred to as channels.

The bumps 503 may be attached on an upper surface of the package substrate 560, and solder balls 504 may be attached on a lower surface of the package substrate 560. For example, the bumps 503 may be flip-chip bumps. The interposer 550 may be stacked on the package substrate 560 through the bumps 503. The semiconductor package 500 may exchange signals with any other external package or semiconductor devices through the solder balls 504. For example, the package substrate 560 may be a printed circuit board (PCB).

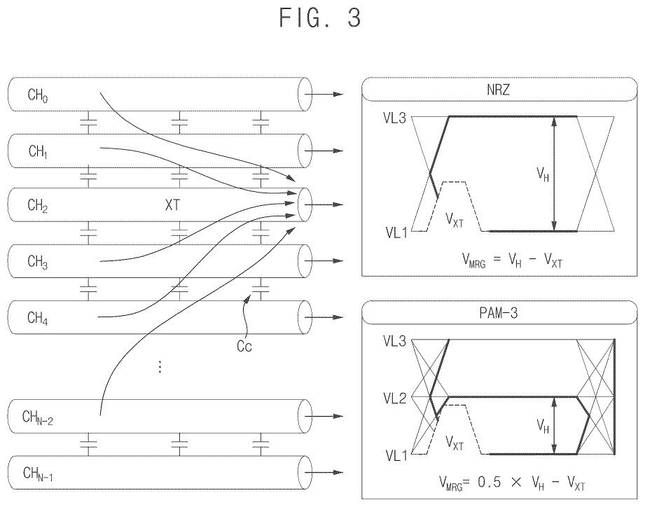

FIG. 3 is a diagram for explaining crosstalk occurring in channels of the semiconductor package of FIG. 2.

Referring to FIG. 3, when a number of channels 555 formed in the interposer 550, a channel pitch corresponding to a gap between the channels 555, the reduced channel pitch increases coupling capacitance between the channels 555 and the increased coupling capacitance causes a crosstalk XT.

In a non return to zero (NRZ) signaling, a difference between the first voltage level VL1 and the second voltage level VL2 corresponds to V_{H} and a voltage margin V_{MRG} corresponds to V_{H}-V_{XT} (a voltage level of the crosstalk XT). In the PAM-3 signaling, a difference between the first voltage level VL1 and the third voltage level VL3 corresponds to V_{H} and a voltage margin V_{MRG} corresponds to V_{H}/2−V_{XT}. Therefore, the effect of the crosstalk XT on PAM-3 signaling is about twice as sever as the effect of the crosstalk XT on the NRZ signaling.

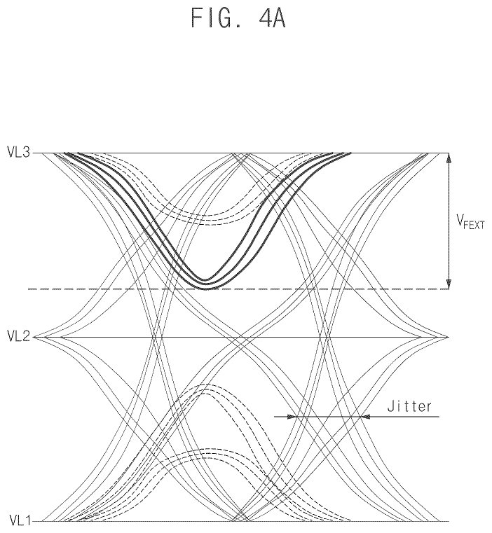

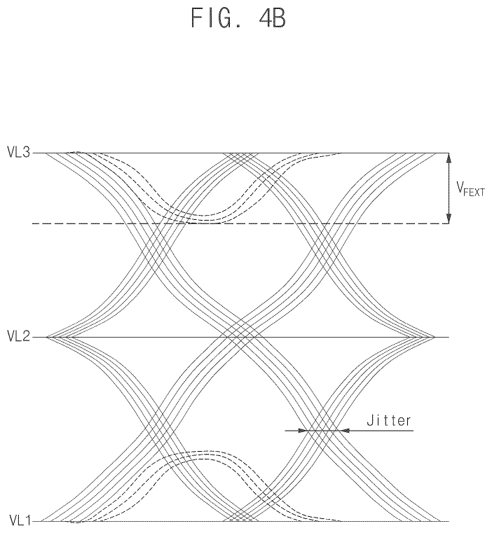

FIG. 4A is an eye diagram of a PAM-3 signal when an encoding scheme avoiding maximum transition is not used.

Referring to FIG. 4A, when the encoding scheme avoiding maximum transition is not used, it is noted that the PAM-3 signal suffers from increased jitter caused by the maximum transitions and increased voltage level V_{FEXT} of a far-end crosstalk.

FIG. 4B is an eye diagram of a PAM-3 signal when an encoding scheme avoiding maximum transition is used.

Referring to FIG. 4B, when the encoding scheme avoiding maximum transition according to example implementations is used, it is noted that jitter and voltage level V_{FEXT} of a far-end crosstalk are largely reduced when FIG. 4B is compared with FIG. 4A.

FIG. 5 is a block diagram illustrating an example of the transmitter in the system of FIG. 1 according to example implementations.

Referring to FIG. 5, the transmitter 100 may include a pseudo random binary sequence (PRBS) generator 110, a first encoder 130, a second encoder 150, a third encoder 200, a serializer 250, a first pulse generator PG1 270, a second pulse generator PG2 290, buffers 310 and 315, a driver 320 and a clock distribution network 190. The clock distribution network 190 may include a plurality of clock dividers 191, 193 and 195.

The first encoder 130 may be referred to as a PAM-3 encoder, the second encoder may be referred to as a 3T4T encoder, the third encoder 200 may be referred to as a feed-forward equalization (FFE) encoder and the driver 320 may be referred to as a PAM-3 driver.

The PRBS generator 110 may generate a plurality of PRBSs PRBa, PRBb and PRBc. Each of the plurality of PRBSs PRBa, PRBb and PRBc may have a binary voltage level.

The first encoder 130 may receive the plurality of PRBSs PRBa, PRBb and PRBc and may encode the plurality of PRBSs PRBa, PRBb and PRBc into a first multi-level data MLDa and a second multi-level data MLDb, each of which has a first voltage level, a second voltage level and a third voltage level.

The second encoder 150 may receive the first multi-level data MLDa and the second multi-level data MLDb, may group each of the first multi-level data MLDa and the second multi-level data MLDb into a K-bit code (K is a three), and may encode the grouped K-bit code to (K+1)-bit code T4_a and T4_b based on a mapping table with avoiding a maximum transition of the (K+1)-bit code T4_a and T4_b. Avoiding a maximum transition can refer to maintaining a difference in values of any two adjacent or consecutive bits of the (K+1)-bit code to less than a difference between highest and lowest configured values that a bit can have in the (K+1)-bit code.

The third encoder 200 may receive a data D_ADJ on at least one adjacent channel, may detect a transition of the data D_ADJ on the at least one adjacent channel, may generate a first control code CCD1 and a second control code CCD2 for cancelling a crosstalk generated by the transition of the data D_ADJ based on the detected transition and may generate a first encoded data ED1 and a second encoded data ED2 based on the (K+1)-bit code T4_a and T4_b.

The serializer 250 may generate a first serial code SCa by serializing the first control code CCD1, may generate a second serial code SCb by serializing the second control code CCD2, may generate a first serial data SD1 by serializing the first encoded data ED1 and may generate a second serial data SDb by serializing the second encoded data EDb.

The first pulse generator 270 may operate based on a first clock signal CLK11, may generate a pull-up control code PUCD based on the first serial code SCa obtained by serializing the first control code CCD1, and may provide the pull-up control code PUCD to the driver 320. The second pulse generator 290 may operate based on the first clock signal CLK11, may generate a pull-down control code PDCD based on the second serial code SCb obtained by serializing the second control code CCD2, and may provide the pull-down control code PDCD to the driver 320.

The first buffer 310 may buffer the first serial data SDa and provide the first serial data SDa to the driver 320 and the second buffer 315 may buffer the second serial data SDb and provide the second serial data SDb to the driver 320.

The driver 320 may generate the output data signal TX_OUT by driving the first serial data SDa and the second serial data SDb based on the pull-up control code PUCD and the pull-down control code PDCD and may transmit the output data signal TX_OUT to the receiver 400 through the channel 50 in FIG. 1. As mentioned above, the first serial data SDa may be obtained by serializing the first encoded data ED1 that is generated based on the (K+1)-bit code T4_a and the second serial data SDb may be obtained by serializing the second encoded data EDb that is generated based on the (K+1)-bit code T4_b.

The clock divider 191 may generate a second clock signal CLK12 by dividing a frequency of the first clock signal CLK11 and may provide the second clock signal CLK12 to the serializer 250. The clock divider 193 may generate a third clock signal CLK13 by dividing a frequency of the second clock signal CLK12 and may provide the third clock signal CLK13 to the first encoder 130, the second encoder 150 and the third encoder 200. The clock divider 195 may generate a fourth clock signal CLK14 by dividing a frequency of the third clock signal CLK13 and may provide the fourth clock signal CLK14 to the PRBS generator 110.

The frequency of the second clock signal CLK12 may be smaller than the frequency of the first clock signal CLK11, the frequency of the third clock signal CLK13 may be smaller than the frequency of the second clock signal CLK12, and the frequency of the fourth clock signal CLK14 may be smaller than the frequency of the third clock signal CLK13.

The serializer 250 may operate based on the second clock CLK12, the first encoder 130, the second encoder 150 and the third encoder 200 may operate based on the third clock signal CLK13 and the PRBS generator 110 may operate based on the fourth clock signal CLK14.

The second encoder 150 may avoid a transition from the first voltage level to the third voltage level of the (K+1)-bit code T4_a and T4_b and a transition from the third voltage level to the first voltage level of the (K+1)-bit code T4_a and T4_b and thus, crosstalk and data dependent jitter of the output data signal TX_OUT may be reduced.

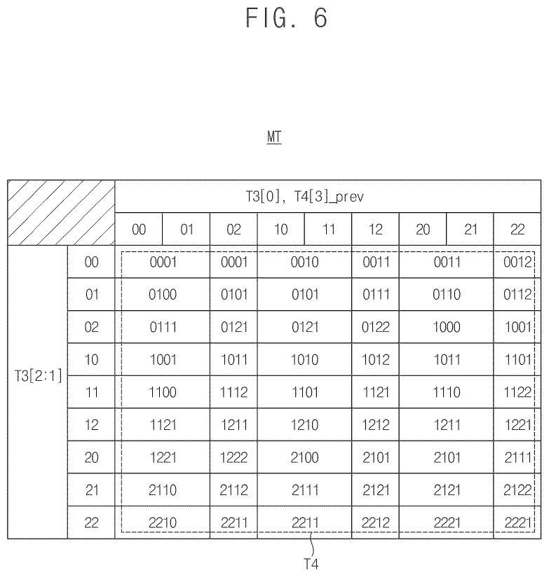

FIG. 6 illustrates a mapping table that the second encoder in FIG. 2 uses according to example implementations.

Referring to FIG. 6, a mapping table MT may indicate (e.g., define) a mapping relation between the K-bit code T3 and the (K+1)-bit code T4, based on upper two bits T3[2:1] of the K-bit code, a least significant bit (LSB) T3[0] of the K-bit code and a most significant bit (MSB) T4[3]_prev of a previous (K+1)-bit code.

For example, when the upper two bits T3[2:1] of the K-bit code is ‘00’ and the LSB T3[0] of the K-bit code and the MSB T4[3]_prev of the previous (K+1)-bit code is ‘00’ or ‘01’, ‘000’ of the K-bit code T3 may be mapped (e.g., encoded) to ‘0001’ of the (K+1)-bit code T4. For example, when the upper two bits T3[2:1] of the K-bit code is ‘00’ and the LSB T3[0] of the K-bit code and the MSB T4[3]_prev of the previous (K+1)-bit code is ‘02’, ‘000’ of the K-bit code T3 may be mapped (e.g., encoded) to ‘0001’ of the (K+1)-bit code T4.

For example, when the upper two bits T3[2:1] of the K-bit code is ‘00’ and the LSB T3[0] of the K-bit code and the MSB T4[3]_prev of the previous (K+1)-bit code is ‘10’ or ‘11’, ‘001’ of the K-bit code T3 may be mapped (e.g., encoded) to ‘0010’ of the (K+1)-bit code T4. For example, when the upper two bits T3[2:1] of the K-bit code is ‘00’ and the LSB T3[0] of the K-bit code and the MSB T4[3]_prev of the previous (K+1)-bit code is ‘12’, ‘001’ of the K-bit code T3 may be mapped (e.g., encoded) to ‘0011’ of the (K+1)-bit code T4.

For example, when the upper two bits T3[2:1] of the K-bit code is ‘00’ and the LSB T3[0] of the K-bit code and the MSB T4[3]_prev of the previous (K+1)-bit code is ‘20’ or ‘21’, ‘002’ of the K-bit code T3 may be mapped (e.g., encoded) to ‘0012’ of the (K+1)-bit code T4. For example, when the upper two bits T3[2:1] of the K-bit code is ‘00’ and the LSB T3[0] of the K-bit code and the MSB T4[3]_prev of the previous (K+1)-bit code is ‘22’, ‘002’ of the K-bit code T3 may be mapped (e.g., encoded) to ‘0012’ of the (K+1)-bit code T4.

For example, when the upper two bits T3[2:1] of the K-bit code is ‘01’ and the LSB T3[0] of the K-bit code and the MSB T4[3]_prev of the previous (K+1)-bit code is ‘00’ or ‘01’, ‘010’ of the K-bit code T3 may be mapped (e.g., encoded) to ‘0100’ of the (K+1)-bit code T4. For example, when the upper two bits T3[2:1] of the K-bit code is ‘00’ and the LSB T3[0] of the K-bit code and the MSB T4[3]_prev of the previous (K+1)-bit code is ‘02’, ‘010’ of the K-bit code T3 may be mapped (e.g., encoded) to ‘0101’ of the (K+1)-bit code T4.

For example, when the upper two bits T3[2:1] of the K-bit code is ‘01’ and the LSB T3[0] of the K-bit code and the MSB T4[3]_prev of the previous (K+1)-bit code is ‘10’ or ‘11’, ‘011’ of the K-bit code T3 may be mapped (e.g., encoded) to ‘0101’ of the (K+1)-bit code T4. For example, when the upper two bits T3[2:1] of the K-bit code is ‘00’ and the LSB T3[0] of the K-bit code and the MSB T4[3]_prev of the previous (K+1)-bit code is ‘12’, ‘011’ of the K-bit code T3 may be mapped (e.g., encoded) to ‘0111’ of the (K+1)-bit code T4.

For example, when the upper two bits T3[2:1] of the K-bit code is ‘01’ and the LSB T3[0] of the K-bit code and the MSB T4[3]_prev of the previous (K+1)-bit code is ‘20’ or ‘11’, ‘012’ of the K-bit code T3 may be mapped (e.g., encoded) to ‘0110’ of the (K+1)-bit code T4. For example, when the upper two bits T3[2:1] of the K-bit code is ‘01’ and the LSB T3[0] of the K-bit code and the MSB T4[3]_prev of the previous (K+1)-bit code is ‘12’, ‘012’ of the K-bit code T3 may be mapped (e.g., encoded) to ‘0112’ of the (K+1)-bit code T4.

For example, when the upper two bits T3[2:1] of the K-bit code is ‘22’ and the LSB T3[0] of the K-bit code and the MSB T4[3]_prev of the previous (K+1)-bit code is ‘00’ or ‘01’, ‘220’ of the K-bit code T3 may be mapped (e.g., encoded) to ‘2210’ of the (K+1)-bit code T4. For example, when the upper two bits T3[2:1] of the K-bit code is ‘22’ and the LSB T3[0] of the K-bit code and the MSB T4[3]_prev of the previous (K+1)-bit code is ‘02’, ‘220’ of the K-bit code T3 may be mapped (e.g., encoded) to ‘2211’ of the (K+1)-bit code T4.

For example, when the upper two bits T3[2:1] of the K-bit code is ‘22’ and the LSB T3[0] of the K-bit code and the MSB T4[3]_prev of the previous (K+1)-bit code is ‘10’ or ‘11’, ‘220’ of the K-bit code T3 may be mapped (e.g., encoded) to ‘2211’ of the (K+1)-bit code T4. For example, when the upper two bits T3[2:1] of the K-bit code is ‘22’ and the LSB T3[0] of the K-bit code and the MSB T4[3]_prev of the previous (K+1)-bit code is ‘12’, ‘220’ of the K-bit code T3 may be mapped (e.g., encoded) to ‘2212’ of the (K+1)-bit code T4.

For example, when the upper two bits T3[2:1] of the K-bit code is ‘22’ and the LSB T3[0] of the K-bit code and the MSB T4[3]_prev of the previous (K+1)-bit code is ‘20’ or ‘21’, ‘220’ of the K-bit code T3 may be mapped (e.g., encoded) to ‘2221’ of the (K+1)-bit code T4. For example, when the upper two bits T3[2:1] of the K-bit code is ‘22’ and the LSB T3[0] of the K-bit code and the MSB T4[3]_prev of the previous (K+1)-bit code is ‘22’, ‘220’ of the K-bit code T3 may be mapped (e.g., encoded) to ‘2221’ of the (K+1)-bit code T4.

Therefore, the (K+1)-bit code T4 does not have a transition from ‘2’ to ‘0’ or ‘0’ to ‘2’. In FIG. 6, ‘0’, ‘1’, and ‘2’ may correspond to the first voltage level VL1, the second voltage level VL2 and the third voltage level VL3, respectively.

Accordingly, the second encoder 150 in FIG. 5 may encode the K-bit code T3 to the (K+1)-bit code T4 with avoiding maximum transition, which is referred to as ‘3T4T’ coding.

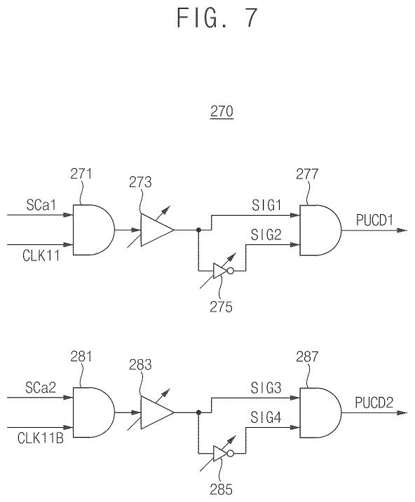

FIG. 7 is a circuit diagram illustrating an example of the first pulse generator in the receiver of FIG. 5 according to example implementations.

Referring to FIG. 7, the first pulse generator 270 may include a first AND gate 271, a first buffer 273, a first inverter 275, a second AND gate 277, a third AND gate 281, a second buffer 283, a second inverter 285 and a fourth AND gate 287.

The first AND gate 271 may perform an AND operation on a first bit of SCa1 the first serial code and the first clock signal CLK11. The first buffer 273 may output a first signal SIG1 by buffering an output of the first AND gate 271. The first inverter 275 may generate a second signal SIG2 by inverting the first signal SIG1. The second AND gate 277 may generate a first bit PUCD1 of the pull-up control code PUCD by performing an AND operation on the first signal SIG1 and the second signal SIG2.

The third AND gate 281 may perform an AND operation on a second bit of SCa2 the first serial code and an inverted version CLK11b the first clock signal CLK11. The second buffer 283 may output a third signal SIG3 by buffering an output of the third AND gate 281. The second inverter 285 may generate a fourth signal SIG4 by inverting the third signal SIG3. The fourth AND gate 287 may generate a second bit PUCD2 of the pull-up control code PUCD by performing an AND operation on the third signal SIG3 and the fourth signal SIG4.

Each of the first buffer 273 and the second buffer 283 may have a first delay time interval that is variable. Each of the first inverter 275 and the second inverter 285 may have a second delay time interval that is variable.

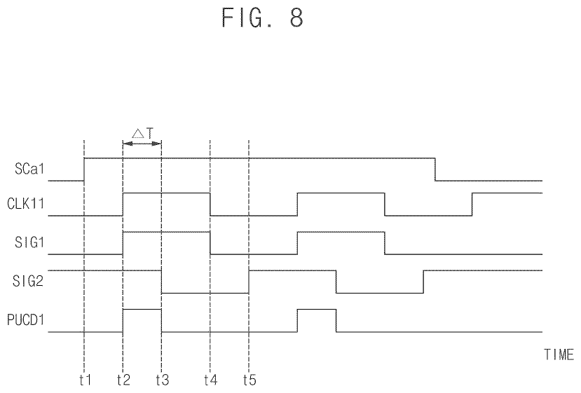

FIG. 8 is a timing diagram illustrating an operation of the first pulse generator in FIG. 7 according to example implementations.

Referring to FIGS. 7 and 8, at a first time point t1, the first bit of SCa1 the first serial code transits to a logic high level and is maintained at a logic high level from the first time point t1. At a second time point t2, the first clock signal CLK11 transits to a logic high level and is maintained at a logic high level until a fourth time point t4 and transits to a logic low level at the fourth time point t4.

The first signal SIG1, an output of the first buffer 273, transits to a logic high level at a second time point t2, is maintained at a logic high level until the fourth time point t4 and transits to a logic low level at the fourth time point t4. The second signal SIG2, an output of the first inverter 275, transits to a logic low level at a third time point t3, is maintained at a logic high level until a fifth time point t5 and transits to a logic high level at the fifth time point t5. A gap between the second time point t2 and the third time point t3 may correspond to a second delay time interval ΔT of the first inverter 275 and the first bit PUCD1 of the pull-up control code PUCD may be a pulse signal that is activated during the second delay time interval ΔT. The second delay time interval ΔT may be variable.

An activation time interval of the first bit PUCD1 of the pull-up control code PUCD is described with reference to FIG. 8, similar description may be applied to an activation time interval of the second bit PUCD2 of the pull-up control code PUCD.

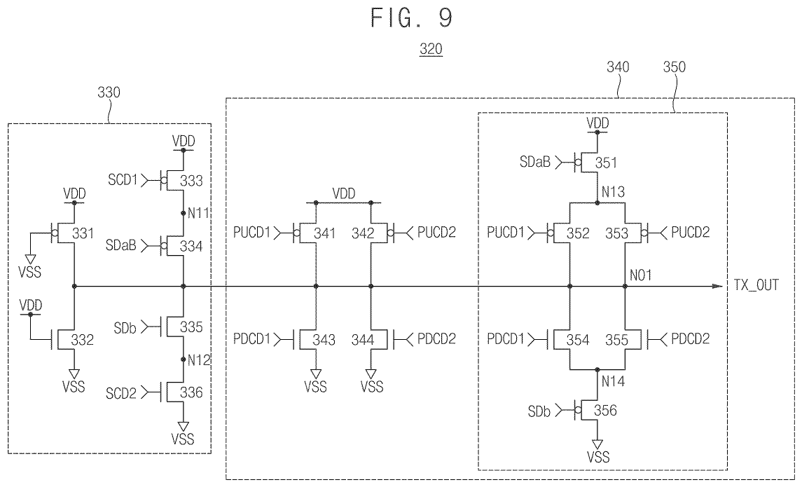

FIG. 9 is a circuit diagram illustrating an example of the driver in the transmitter of FIG. 5 according to example implementations.

Referring to FIG. 9, the driver 320 may include a strength adjusting circuit 330 and a driver circuit 340.

The strength adjusting circuit 330 may compensate for nonlinearity of the output data signal TX_OUT by adjusting an amount of a current provided to an output node NO1 providing the output data signal TX_OUT, based on a first strength control code SCD1, a second strength control code SCD2, the first serial data SDa and the second serial data SDb.

The driver circuit 340 may generate the output data signal TX_OUT by driving the output node NO1, based on the pull-up control code PUCD, the pull-down control code PDCD, the first serial data SDa and the second serial data SDb.

The strength adjusting circuit 330 may include p-channel metal-oxide semiconductor (PMOS) transistors 331, 333 and 334 and n-channel metal-oxide semiconductor (NMOS) transistors 332, 335 and 336.

The PMOS transistor 331 may be coupled between a power supply voltage VDD and the output node NO1 and may have a gate coupled to a ground voltage VSS. Therefore, the PMOS transistor 331 may be always turned-on and may provide a current to the output node NO1. The NMOS transistor 332 may be coupled between the output node NO1 and the ground voltage VSS and may have a gate coupled to the power supply voltage VDD. Therefore, the NMOS transistor 332 may be always turned-on and may discharge the output node NO1. That is, the PMOS transistor 331 and the NMOS transistor 332 may be always turned-on and may maintain an intermediate voltage level (e.g., the second voltage level VL2) of the output data signal TX_OUT.

The PMOS transistor 333 may be coupled between the power supply voltage VDD and a node NO11 and may have a gate receiving the first strength control code SCD1. The PMOS transistor 334 may be coupled between the node NO11 and the output node NO1 and may have a gate receiving an inverted version SDaB of the first serial data SDa. Therefore, the PMOS transistor 334 may generate a high voltage level (e.g., the third voltage level VL3) of the output data signal TX_OUT, based on the inverted version SDaB of the first serial data SDa and the PMOS transistor 333 may compensate for a nonlinearity due to variance of process-voltage- temperature PVT by adjusting an amount of the current provided to the output node NO1 based on the first strength control code SCD1.

The NMOS transistor 335 may be coupled between the output node NO1 and a node NO12 and may have a gate receiving the second serial data SDb. The NMOS transistor 336 may be coupled between the node NO12 and the ground voltage VSS and may have a gate receiving the second strength control code SCD2. Therefore, the NMOS transistor 335 may generate a low voltage level (e.g., the first voltage level VL1) of the output data signal TX_OUT, based on the second serial data SDb and the NMOS transistor 336 may compensate for a nonlinearity due to variance of process-voltage-temperature PVT by adjusting an amount of the current provided to the output node NO1 based on the second strength control code SCD2.

The driver circuit 340 may include a first PMOS transistor 341, a second PMOS transistor 342, a first NMOS transistor 343, a second NMOS transistor and an asymmetric feed-forward equalizer 350. The asymmetric feed-forward equalizer 350 may include a third PMOS transistor 351, a fourth PMOS transistor 352, a fifth PMOS transistor 353, a third NMOS transistor 354, a fourth NMOS transistor 355 and a fifth NMOS transistor 356.

The first PMOS transistor 341 may be coupled between the power supply voltage VDD and the output node NO1 and may have a gate receiving the first bit PUCD1 of the pull-up control code. The second PMOS transistor 342 may be coupled between the power supply voltage VDD and the output node NO1 in parallel with the first PMOS transistor 341 and may have a gate receiving a second bit PUCD2 of the pull-up control code. Therefore, the first PMOS transistor 341 and the second PMOS transistor 342 may perform a crosstalk cancellation based on the feed-forward equalization by pulling-up the output node NO1 based on the pull-up control code PUCD.

The first NMOS transistor 343 may be coupled between the ground voltage VSS and the output node NO1 and may have a gate receiving the first bit PDCD1 of the pull-down control code. The second NMOS may be coupled between the ground voltage VSS and the output node NO1 in parallel with the first NMOS transistor 343 and may have a gate receiving a second bit PDCD2 of the pull-down control code. Therefore, the first NMOS transistor 343 and the second NMOS transistor 343 may perform a crosstalk cancellation based on the feed-forward equalization by pulling-down the output node NO1 based on the pull-down control code PDCD.

The third PMOS transistor 351 may be coupled between the power supply voltage VDD and a first node N13 and may have a gate receiving the inverted version SDa of the first serial data SDa. The fourth PMOS transistor 352 may be coupled between the first node N13 and the output node NO1 and may have a gate receiving the first bit PUCD1 of the pull-up control code. The fifth PMOS transistor 353 may be coupled between the first node N13 and the output node NO1 in parallel with the fourth PMOS transistor 352 and may have a gate receiving the second bit PUCD2 of the pull-up control code. Therefore, the third PMOS transistor 351, the fourth PMOS transistor 352 and the fifth PMOS transistor 353 may pull-up the output node NO1 based on the inverted version SDa of the first serial data SDa and the pull-up control code PUCD.

The third NMOS transistor 354 may be coupled between the second node N14 and the output node NO1 and may have a gate receiving the first bit PDCD1 of the pull-down control code. The fourth NMOS transistor 355 may be coupled between the second node N14 and the output node NO1 in parallel with the third NMOS transistor 354 and may have a gate receiving the second bit PDCD2 of the pull-down control code. The fifth NMOS transistor 356 may be coupled between the ground voltage VSS and the second node N14 and may have a gate receiving the second serial data SDb. Therefore, the third NMOS transistor 354, the fourth NMOS transistor 355 and the fifth NMOS transistor 356 may pull-down the output node NO1 based on the second serial data SDb and the pull-down control code PDCD.

A voltage level of the output data signal TX_OUT, which is provided at the output node NO1, may be determined by current driving capability of the third PMOS transistor 351, the fourth PMOS transistor 352 and the fifth PMOS transistor 353 and by current driving capability of the third NMOS transistor 354, the fourth NMOS transistor 355 and the fifth NMOS transistor 356. In PAM_3 signaling, the current driving capability of the third PMOS transistor 351, the fourth PMOS transistor 352 and the fifth PMOS transistor 353 is different from the current driving capability of the third NMOS transistor 354, the fourth NMOS transistor 355 and the fifth NMOS transistor 356, a strength of the asymmetric feed-forward equalizer 350 may be adjusted based on a voltage level of the output data signal TX_OUT. The asymmetric feed-forward equalizer 350 may be asymmetrically designed to generate a same compensation voltage for each of the voltage levels of the output data signal TX_OUT and thus may reduce a jitter occurring in the output data signal TX_OUT.

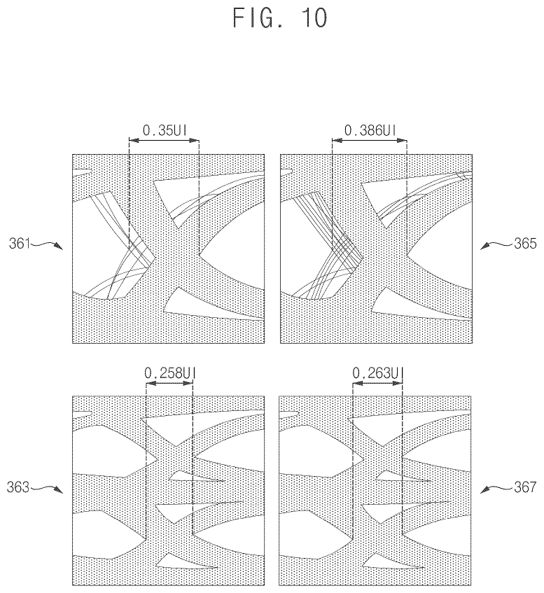

FIG. 10 illustrates data dependent jitters when the NRZ signaling and the 3T4T coding with avoiding maximum transition are used according to PRBS patterns.

In FIG. 10, a reference numeral 361 and a reference numeral 361 illustrate data dependent jitters when the NRZ signaling and the 3T4T coding are used according to PRBS_15 pattern, respectively and a reference numeral 365 and a reference numeral 367 illustrate data dependent jitters when the NRZ signaling and the 3T4T coding are used according to PRBS_31 pattern, respectively.

Referring to FIG. 10, it is noted that the data dependent jitter is more reduced when the 3T4T coding is used with respect to the PRBS_15 pattern and the PRBS_31 pattern compared with a case when the NRZ signaling is used with respect to the PRBS_15 pattern and the PRBS_31 pattern.

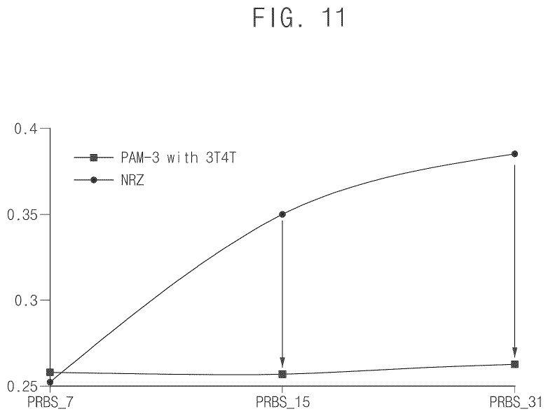

FIG. 11 is a graph illustrating data dependent jitters when the NRZ signaling and the 3T4T coding with avoiding maximum transition are used according to PRBS patterns.

In FIG. 11, PRBS patterns PRBS_7, PRBS_15 and PRBS_31 are exemplified. Referring to FIG. 11, it is noted that the data dependent jitter is more reduced when the 3T4T coding is used with respect to the PRBS_15 pattern and the PRBS_31 pattern compared with a case when the NRZ signaling is used with respect to the PRBS_15 pattern and the PRBS_31 pattern.

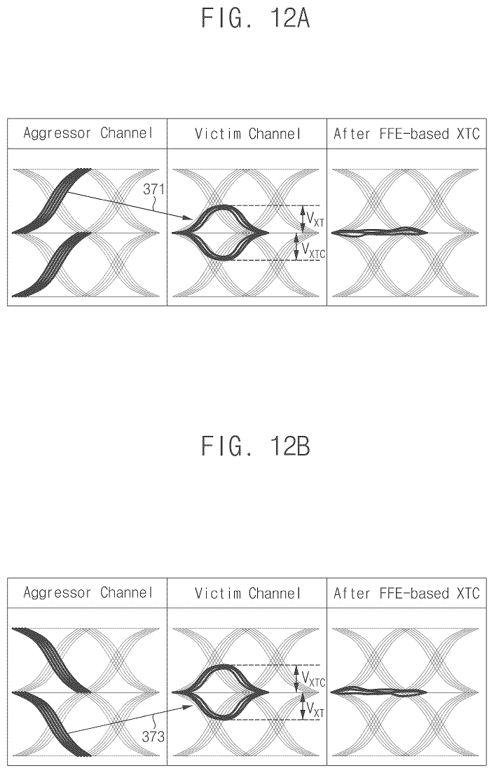

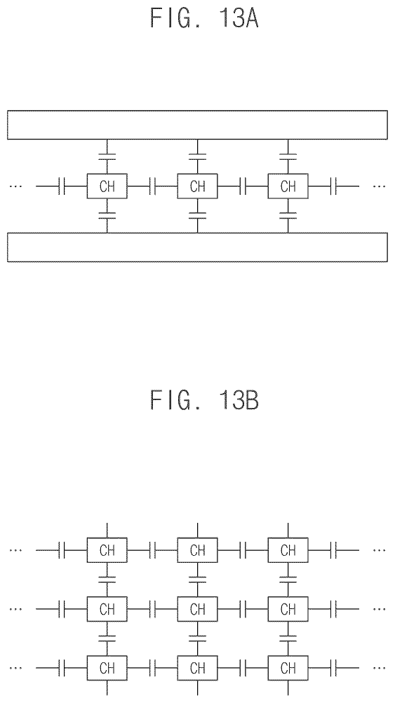

FIGS. 12A and 12B are diagrams for explaining that the third encoder in FIG. 5 cancels the crosstalk generated by transition of a data on an adjacent channel, respectively.

Referring to FIG. 12A, when a data on the adjacent channel Aggressor Channel transits up-word, a crosstalk V_{XT} occurs in a target channel Victim Channel. The third encoder 200 may generate a crosstalk cancellation signal V_{XTC} that has a phase difference of 180 degrees with respect to the crosstalk V_{XT} and the third encoder 200 may output a crosstalk-cancelled signal.

Referring to FIG. 12B, when a data on the adjacent channel Aggressor Channel transits down-word, a crosstalk V_{XT} occurs in a target channel Victim Channel. The third encoder 200 may generate a crosstalk cancellation signal V_{XTC} that has a phase difference of 180 degrees with respect to the crosstalk V_{XT} and the third encoder 200 may output a crosstalk-cancelled signal.

FIGS. 13A and 13B illustrate that the third encoder in FIG. 5 adjusts a number of bits in each of the first control code and the second control code based on a number of adjacent channels, respectively.

Referring to FIGS. 13A and 13B, the third encoder 200 may adjust a number of bits in each of the first control code CCD1 and the second control code CCD2 differently when the adjacent channels are two or four. That is, the third encoder 200 may increase a number of bits in each of the first control code CCD1 and the second control code CCD2 when a number of the adjacent channel increases.

Therefore, the transmitter according 100 to example implementations may reduce the crosstalk and the jitter of the output data signal on the channel by converting 3-bit code to 4-bit code with avoiding maximum transition and transmitting converted signal through the channel.

FIG. 14 is a block diagram illustrating an example of the receiver in the system of FIG. 1 according to example implementations.

Referring to FIG. 14, the receiver 400 may include an amplifier TIA 410, a signal converter 420, a first comparator 440, a second comparator 445, a deserializer 450, a first decoder 460, a second decoder 470, a PRBS checker 480 and a clock network 490. The first decoder 460 may be referred to as a 3T4T decoder and the second decoder 470 may be referred to as a PAM-3 decoder.

The amplifier 410 may receive the input signal RX_IN having a first voltage level, a second voltage level and a third voltage level through the channel 50 and may generate an amplified signal AS by amplifying the input signal RX_IN.

The signal converter 420 may receive the amplified signal AS and may convert the amplified signal AS that is a single-ended signal into a differential signal including a first signal DFS1 and a second signal DFS2.

The first comparator 440 may generate a first comparison signal CS1 by performing a sampling operation to compare the first signal DFS1 with a first reference voltage, based on a multi-phase clock signal CLK21_4P. The second comparator 445 may generate a second comparison signal CS2 by performing a sampling operation to compare the second signal DFS2 with a second reference voltage, based on the multi-phase clock signal CLK21_4P.

The deserializer 450 may generate a first deserialized signal DS1 by deserializing the first comparison signal CS1 and may generate a second deserialized signal DS2 by deserializing the second comparison signal CS2.

The first decoder 460 may receive the first deserialized signal DS1 and the second deserialized signal DS2, may group each of the first deserialized signal DS1 and the second deserialized signal DS2 into a (K+1)-bit code and may generate, in response to a number of consecutive identical bits of the (K+1)-bit code being equal to or smaller than K, a first decoded signal DEC1 and a second decoded signal DEC2 by decoding the grouped (K+1)-bit code into K-bit code based on a mapping table.

The second decoder 470 may receive the first decoded signal DEC1 and a second decoded signal DEC2 and may decode the first decoded signal DEC1 and the second decoded signal DEC2 to PRBSs PRBa1, PRBb1 and PRBc1, based on a voltage level of each of the first decoded signal DEC1 and the second decoded signal DEC2.

The PRBS checker 480 may selectively generate an error signal ERR by checking the PRBSs PRBa1, PRBb1 and PRBc1. The PRBS checker 480 may selectively generate an error signal ERR based on each of the PRBSs PRBa1, PRBb1 and PRBc1 is the same as respective one of the PRBSs PRBa, PRBb and PRBc.

The clock distribution network 490 may include a multi-phase clock signal generator MPCG 491, a first clock divider 492, a second clock divider 493 and a fourth clock divider 494.

The MPCG 491 may receive a first clock signal CLK21, may generate the multi-phase clock signal CLK21_4P having multi-phases by shifting a phase of the first clock signal CLK21 and may provide the multi-phase clock signal CLK21_4P to the first comparator 440 and the second comparator 445.

The first clock divider 492 may generate a second clock signal CLK22 by dividing a frequency of one of the multi-phase clock signal CLK21_4P and may provide the second clock signal CLK22 to the deserializer 450.

The second clock divider 493 may generate a third clock signal CLK23 by dividing a frequency of the second clock signal CLK22 and may provide the third clock signal CLK23 to the first decoder 460 and the second decoder 470.

The third clock divider 494 may generate a fourth clock signal CLK24 by dividing a frequency of the third clock signal CLK23 and may provide the fourth clock signal CLK24 to the PRBS checker 480.

The frequency of the second clock signal CLK22 may be smaller than the frequency of the multi-phase clock signal CLK21_4P, the frequency of the third clock signal CLK23 may be smaller than the frequency of the second clock signal CLK22 and the frequency of the fourth clock signal CLK24 may be smaller than the frequency of the third clock signal CLK23.

The first comparator 440 and the second comparator 445 may operate based on the multi-phase clock signal CLK21_4P, the deserializer 450 may operate based on the second clock signal CLK22, the first decoder 460 and the second decoder 470 may operate based on the third clock signal CLK23 and the PRBS checker 480 may operate based on the fourth clock signal CLK24.

In example implementations, the first encoder 130 in FIG. 5 may encode the input data instead of the PRBSs PRBa, PRBb and PRBc into the first multi-level data MLDa and the second multi-level data MLDa which have a first voltage level, a second voltage level and a third voltage level. In this case, the second decoder 470 in FIG. 14 may decode the first decoded signal DEC1 and the second decoded signal DEC2 to the output data signal RX_OUT based on voltage levels of each of the first decoded signal DEC1 and the second decoded signal DEC2.

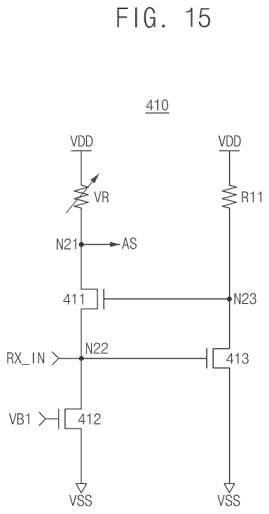

FIG. 15 is a circuit diagram illustrating an example of the amplifier in the receiver of FIG. 14 according to example implementations.

Referring to FIG. 15, the amplifier 410 may include NMOS transistors 411, 412 and 413, a variable resistor VR and a resistor R11.

The variable resistor VR may be coupled between the pawer supply voltage VDD and a node N21. The NMOS transistor 411 may be coupled between the node N21 and a node N23 and may have a gate coupled to a node N23. The NMOS transistor 412 may be coupled between the node N22 and the ground voltage VSS and may have a gate receiving a bias voltage VB1.

The resistor R11 may be coupled between the power supply voltage VDD and the node N23. The NMOS transistor 413 may be coupled between the node N23 and the ground voltage VSS and may have a gate coupled to the node N22 and receiving the input data signal RX_IN.

When the input data signal RX_IN is applied to the gate of the NMOS transistor 413 through the node N22, the NMOS transistor 413 may be selectively turned-on based on a voltage level of the input data signal RX_IN and may selectively discharge the node N23.

When the NMOS transistor 412 is turned-on based on the bias voltage VB1 and the NMOS transistor 411 is selectively turned-on based on a voltage level at the node N23, a voltage level at the node N21 may vary and the voltage at the node N21 may be output as the amplified signal AS.

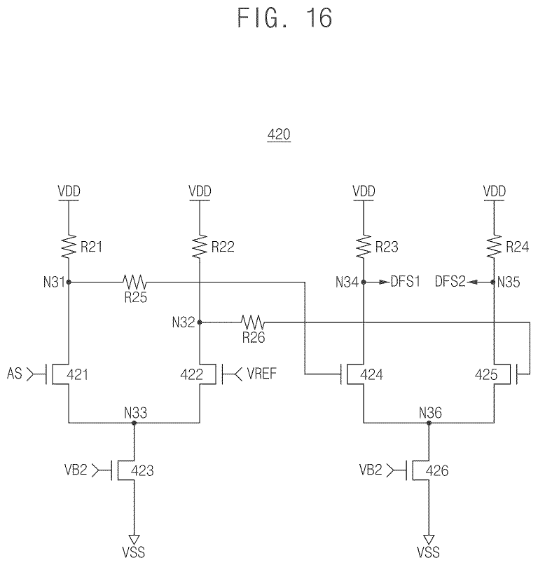

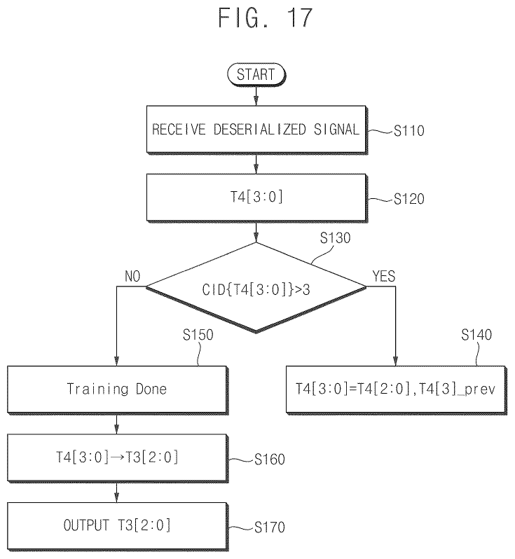

FIG. 16 is a circuit diagram illustrating an example of the signal converter in the receiver of FIG. 14 according to example implementations.

Referring to FIG. 16, the signal converter 420 may include first through sixth resistors R21, R22m R23, R24, R25 and R26 and first through sixth NMOS transistors 421, 422, 423, 424, 425 and 426.

The first resistor R21 may be coupled between the power supply voltage VDD and a first node N31, and the second resistor R22 may be coupled between the power supply voltage VDD and a second node N32. The first NMOS transistor 421 may be coupled between the first node N31 and a third node N33 and may have a gate receiving the amplified signal AS. The second NMOS transistor 422 may be coupled between the second node N32 and the third node N33 and may have a gate receiving a reference voltage VREF. The third NMOS transistor 423 may be coupled between the third node N33 and the ground voltage VSS and may have a gate receiving a bias voltage VB2.

The third resistor R23 may be coupled between the power supply voltage VDD and a fourth node N34. The fourth resistor R24 may be coupled between the power supply voltage VDD and a fifth node N35. The fourth NMOS transistor 424 may be coupled between the fourth node N34 and a sixth node N36 and may have a gate connected to a fifth resistor R25 coupled to the first node N31. The fifth NMOS transistor 425 may be coupled between the fifth node N35 and the sixth node N36 and may have a gate connected to a sixth resistor R26 coupled to the second node N32. The sixth NMOS transistor 426 may be coupled between the sixth node N36 and the ground voltage VSS and may have a gate receiving the bias voltage VB2.

When the third NMOS transistor 423 and the sixth NMOS transistor 426 are turned-on in response to the bias voltage VB2, and the amplified signal AS is applied to the gate of the first NMOS transistor 421, the first NMOS transistor 421 is selectively turned-on based on a voltage level of the amplified signal AS and a voltage level at the first node N31 may vary. In addition, the second NMOS transistor 422 is selectively turned-on based on the reference voltage VREF and a voltage level at the second node N32 may vary.

The fourth NMOS transistor 424 is selectively turned-on based on a voltage level at the first node N31, a voltage level at the fourth node N34 may vary, and a voltage at the fourth node N34 may be provided as the first signal DSF1. The fifth NMOS transistor 425 is selectively turned-on based on a voltage level at the second node N32, a voltage level at the fifth node N35 may vary, and a voltage at the fifth node N35 may be provided as the second signal DSF2.

The signal convert 420 may convert the amplified signal AS (e.g., a single-ended) signal to a differential signal including the first signal DSF1 and the second signal DSF2.

FIG. 17 is a flow chart illustrating an operation of the first decoder in FIG. 14 according to example implementations.

Referring to FIGS. 14 and 17, the first decoder 460 may receive the first deserialized signal DS1 and the second deserialized signal DS2 (operation S110), and may group each of the first deserialized signal DS1 and the second deserialized signal DS2 into the (K+1)-bit code T4[3:0] (operation S120).

The first decoder 460 may determine whether a number of consecutive identical bits CID{T4[3:0]} of the (K+1)-bit code T4[3:0] is greater than K (K is three) (operation S130).

When the number of consecutive identical bits CID{T4[3:0]} of the (K+1)-bit code T4[3:0] is greater than K (YES in S130), the first decoder 460 may obtain lower three bits T4[2:0] of the (K+1)-bit code T4[3:0] and an MSB T4[3]_prev of a previous (K+1)-bit code as a present (K+1)-bit code T4[3:0] by shifting the (K+1)-bit code T4[3:0] by one bit, and may determine a number of consecutive identical bits CID{T4[3:0]} of the (K+1)-bit code T4[3:0] is greater than K (operation S130).

When the number of consecutive identical bits CID{T4[3:0]} of the (K+1)-bit code T4[3:0] is not greater than K (NO in S130), that is, when the number of consecutive identical bits CID{T4[3:0]} of the (K+1)-bit code T4[3:0] is equal to or smaller than K, the first decoder 460 determines that a training is done (operation S150), may decode (map) the (K+1)-bit code T4[3:0] to K-bit code T3[2:0] (operation S160) and may output the K-bit code T3[2:0] to the second decoder 470 (operation S170).

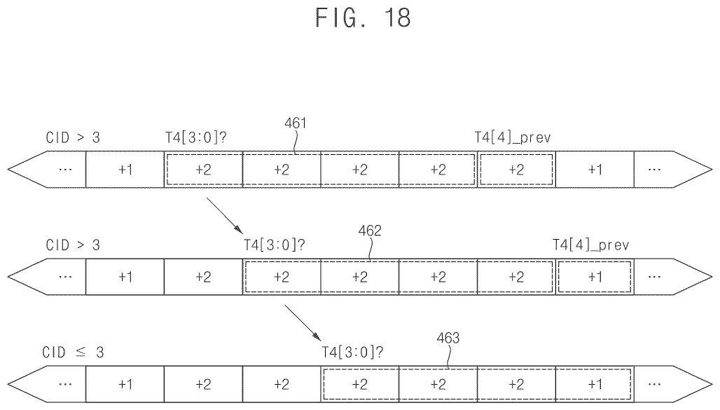

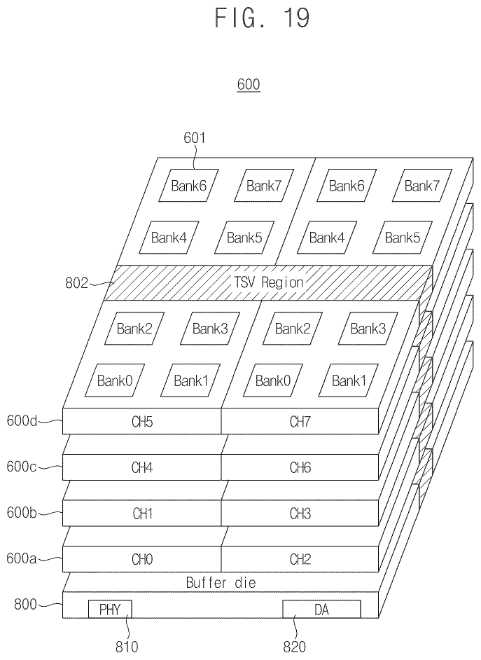

FIG. 18 illustrates that the first decoder in the receiver of FIG. 14 performs a self training.

Referring to FIG. 18, when the number of consecutive identical bits CID{T4[3:0]} of the (K+1)-bit code T4[3:0] is greater than K, the first decoder 460 may shift the K+1)-bit code T4[3:0] by one bit until the number of consecutive identical bits CID{T4[3:0]} of the (K+1)-bit code T4[3:0] becomes equal to or smaller than K.

FIG. 19 is a block diagram illustrating an example of the stacked memory device in FIG. 2 according to example implementations.

Referring to FIG. 19, the stacked memory device 600 may include a buffer die 800 and a plurality of core dies 600a, 600b, 600c and 600d. For example, the buffer die 800 may be also referred to as an “interface die”, a “base die”, a “logic die”, or a “master die”, and each of the core dies 600a, 600b, 600c and 600d may be also referred to as a “memory die” or a “slave die”. An example is illustrated in FIG. 19 as the stacked memory device 600 includes the four core dies 600a, 600b, 600c and 600d, but the number of core dies may be variously changed. For example, the stacked memory device 600 may include 8, 12, or 16 core dies.

The buffer die 800 and the core dies 600a, 600b, 600c and 600d may be stacked and may be electrically connected by using through silicon vias (TSV). As such, the stacked memory device 600 may have a three-dimensional memory structure in which the plurality of dies 600a, 600b, 600c and 600d are stacked. For example, the stacked memory device 600 may be implemented in compliance with the HBM or hybrid memory cube (HMC) standard.

The stacked memory device 600 may support a plurality of channels (or vaults) that are functionally independent of each other. For example, as illustrated in FIG. 19, the stacked memory device 600 may support 8 channels CH0 to CH7. In the case where each of the channels CH0 to CH7 supports 128 DQ input/outputs (I/O)s, the stacked memory device 600 may support 1204 DQ I/Os. However, implementations are not limited thereto. For example, the stacked memory device 600 may support 1024 or more DQ I/Os and may support 8 or more channels (e.g., 16 channels). In the case where the stacked memory device 600 supports 16 channels, each of the channels may support 64 DQ I/Os.

Each of the core dies 600a, 600b, 600c and 600d may support at least one channel. For example, as illustrated in FIG. 19, the core dies 600a, 600b, 600c and 600d may support channel pairs CH0 and CH2, CH1 and CH3, CH4 and CH6, and CH5 and CH7, respectively. In this case, the core dies 600a, 600b, 600c and 600d may support different channels. However, implementations are not limited thereto. For example, at least two of the core dies 600a, 600b, 600c and 600d may support the same channel. For example, each of the core dies 600a, 600b, 600c and 600d may support the first channel CH0.

Each of channels may form an independent command and data interface. For example, channels may be independently clocked based on independent timing requirements and may not be synchronized. For example, based on an independent command, each channel may change a power state or may perform a refresh operation.

Each of the channels may include a plurality of memory banks 601. Each of the memory banks 601 may include memory cells connected with word lines and bit lines, a row decoder, a column decoder, a sense amplifier, etc. For example, as illustrated in FIG. 19, each of the channels CH0 to CH7 may support 8 memory banks 401 such as memory banks Bank0, Bank1, Bank2, Bank3, Bank4, Bank5, Bank6 and Bank7. However, implementations are not limited thereto. For example, each of the channels CH0 to CH7 may support 8 or more memory banks 601. An example is illustrated in FIG. 19 as memory banks belonging to one channel are included in one core die, but memory banks belonging to one channel may be distributed into a plurality of core dies. For example, in the case where each of the core dies 600a, 600b, 600c and 600d supports the first channel CH0, memory banks included in the first channel CH0 may be distributed into the core dies600a, 600b, 600c and 600d.

In example implementations, one channel may be divided into two pseudo channels that operate independently of each other. For example, the pseudo channels may share a command and clock inputs (e.g., a clock signal and a clock enable signal) of the corresponding channel but may independently decode and execute commands. For example, in the case where one channel supports 128 DQ I/Os, each of the pseudo channels may support 64 DQ I/Os. For example, in the case where one channel supports 64 DQ I/Os, each of the pseudo channels may support 32 DQ I/Os.

The buffer die 800 and the core dies 600a, 600b, 600c and 600d each may include a TSV region 802. TSVs configured to penetrate the dies 800, 600a, 600b, 600c and 600d may be disposed in the TSV region 802. The buffer die 800 may exchange signals and/or data with the core dies 600a, 600b, 600c and 600d through the TSVs. Each of the core dies 600a, 600b, 600c and 600d may exchange signals and/or data with the buffer die 800 through the TSVs, and the core dies 600a, 600b, 600c and 600d may exchange signals and/or data with each other through the TSVs. In this case, the signals and/or data may be independently exchanged through the corresponding TSVs for each channel. For example, in the case where an external host device transmits a command and an address to the first channel CH0 for the purpose of accessing a memory cell of the first core die 600a, the buffer die 800 may transmit control signals to the first core die 600a through TSVs corresponding to the first channel CH0 and may access the memory cell of the first channel CH0.

The buffer die 800 may include a physical region PHY 810 and a direct access region DA 820.

In example implementations, the buffer die 800 may include a plurality of pins for receiving signals from the external host device.

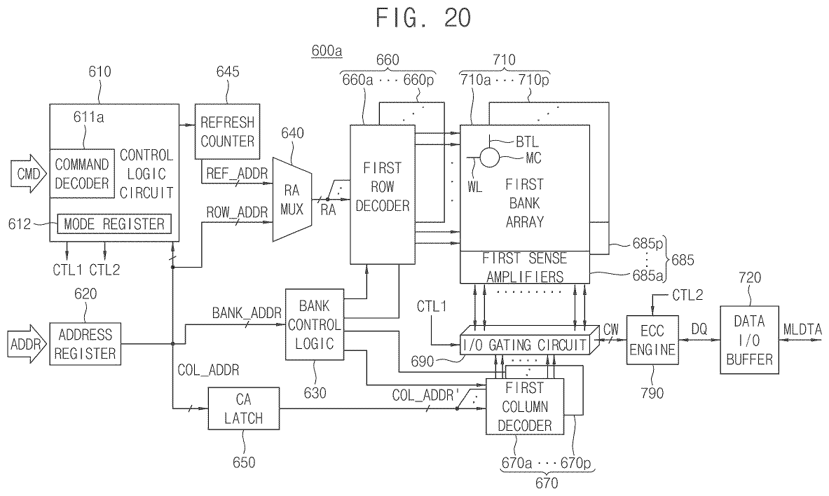

FIG. 20 is a block diagram illustrating an example of the first core die in the stacked memory device of FIG. 19 according to example implementations.

Referring to FIG. 20, the first core die 600a may include a control logic circuit 610, an address register 620, a bank control logic 630, a row address multiplexer 640, a column address latch 650, a row decoder 660, a column decoder 670, a memory cell array 710, a sense amplifier unit 685, an input/output (I/O) gating circuit 690, a refresh counter 645, a data I/O buffer 720a, and an ECC engine 790.

The memory cell array 710 may include first through sixteenth bank arrays 710a~710p. The row decoder 660 may include first through sixteenth row decoders 660a~660p respectively coupled to the first through sixteenth bank arrays 710a~710p. The column decoder 670 may include first through sixteenth column decoders 670a~670p respectively coupled to the first through sixteenth bank arrays 710a~710p. The sense amplifier unit 685 may include first through sixteenth sense amplifiers 685a~685p respectively coupled to the first through sixteenth bank arrays 710a~710p. The first through sixteenth bank arrays 510a~510p, the first through sixteenth row decoders 660a~660p, the first through sixteenth column decoders 670a~670p, and first through sixteenth sense amplifiers 685a~685p may form first through sixteenth banks.

Each of the first through sixteenth bank arrays 710a~710p may include a plurality of memory cells MC, formed at intersections of a plurality of word-lines WL and a plurality of bit-line BTL.

The address register 620 may receive the address ADDR including a bank address BANK_ADDR, a row address ROW_ADDR, and a column address COL_ADDR from the buffer die 800. The address register 620 may provide the received bank address BANK_ADDR to the bank control logic 630, provide the received row address ROW_ADDR to the row address multiplexer 740, and provide the received column address COL_ADDR to the column address latch 750.

The bank control logic 630 may generate bank control signals in response to the bank address BANK_ADDR. One of the first through sixteenth row decoders 660a~660p corresponding to the bank address BANK_ADDR may be activated in response to the bank control signals, and one of the first through sixteenth column decoders 670a~670p corresponding to the bank address BANK_ADDR may be activated in response to the bank control signals.

The row address multiplexer 640 may receive the row address ROW_ADDR from the address register 620, and may receive a refresh row address REF_ADDR from the refresh counter 645. The row address multiplexer 640 may selectively output one of the row address ROW_ADDR and the refresh row address REF_ADDR as a row address RA. The row address RA that is output from the row address multiplexer 440 may be applied to the first through sixteenth row decoders 660a~660p.

The refresh counter 645 may sequentially increase or decrease the refresh row address REF_ADDR under control of the control logic circuit 610.

The activated one of the first through sixteenth row decoders 660a~660p may decode the row address RA that is output from the row address multiplexer 640, and may activate a word-line corresponding to the row address RA. For example, the activated bank row decoder may apply a word-line driving voltage to the word-line corresponding to the row address RA.

The column address latch 650 may receive the column address COL_ADDR from the address register 620, and may temporarily store the received column address COL_ADDR. In example implementations, in a burst mode, the column address latch 650 may generate column addresses COL_ADDR′ that increment from the received column address COL_ADDR. The column address latch 650 may apply the temporarily stored or generated column address COL_ADDR′ to the first through sixteenth column decoders 670a~670p.

The activated one of the first through sixteenth column decoders 670a~670p may decode the column address COL_ADDR′ that is output from the column address latch 650, and may control the I/O gating circuit 690 to output data corresponding to the column address COL_ADDR.

The I/O gating circuit 690 may include circuitry for gating input/output data. The I/O gating circuit 690 may further include read data latches for storing data that is output from the first through sixteenth bank arrays 710a~710p, and write drivers for writing data to the first through sixteenth bank arrays 710a~710p.

A codeword CW that is read from one bank array of the first through sixteenth bank arrays 710a~710p may be sensed by a sense amplifier coupled to the one bank array from which the data is to be read, and may be stored in the read data latches. The codeword CW stored in the read data latches may be provided to the ECC engine 790. The ECC engine 790 may perform an ECC decoding on the codeword CW to provide the data DQ to the data I/O buffer 720. The data I/O buffer 720 may convert the data DQ to a multi-level data MLDTA and may provide the multi-level data MLDTA to the buffer die 800. The data I/O buffer 720 may include the transmitter 100 of FIG. 5.

The data I/O buffer 720 may receive the multi-level data MLDTA from the buffer die 800 and convert the multi-level data MLDTA to the data DQ. The data DQ to be written in one bank array of the first through sixteenth bank arrays 710a~710p may be provided to the ECC engine 790 from the data I/O buffer 720. The ECC engine 790 may perform an ECC encoding on the data DQ to generate parity bits and the ECC engine 790 may provide the data DQ and the parity bits to the I/O gating circuit 690. The I/O gating circuit 690 may write the data DQ and the parity bits in a sub-page in one bank array through the write drivers. The data I/O buffer 720 may include the receiver 400 of FIG. 14.

The ECC engine 790 may perform an ECC encoding and ECC decoding on the data DQ based on a second control signal CTL2 from the control logic circuit 610.

The control logic circuit 610 may control operations of the first core die 600a. The control logic circuit 610 may include a command decoder 611a that decodes the command CMD received from the buffer die 800, and may include a mode register 612 that sets an operation mode of the first core die 600a.

The control logic circuit 610 may generate a first control signal CTL1 to control the I/O gating circuit 690 and may generate the second control signal CTL2 to control the ECC engine 790 by decoding the command CMD.

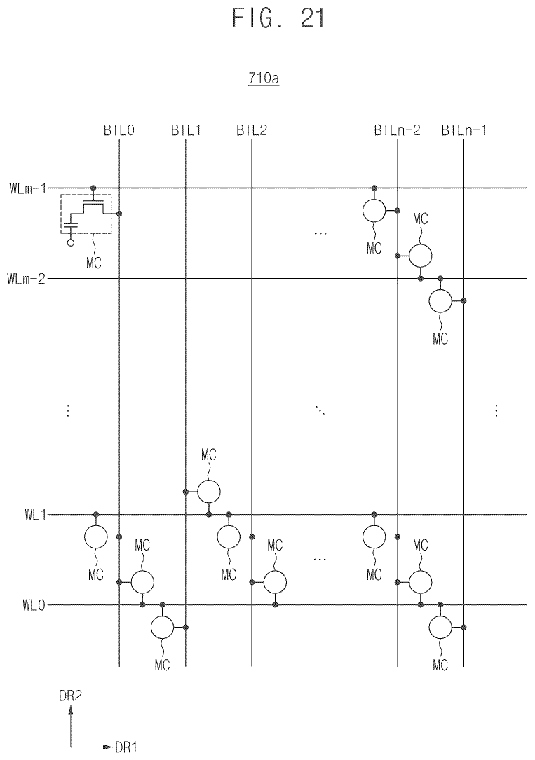

FIG. 21 illustrates an example of a first bank array in the first core die of FIG. 20 according to example implementations.

Referring to FIG. 21, the first bank array 710a may include a plurality of word-lines WL0~WLm-1 (m is a natural number greater than two), a plurality of bit-lines BTL0~BTLn-1 (n is a natural number greater than two), and a plurality of memory cells MCs disposed at intersections between the word-lines WL0~WLm-1 and the bit-lines BTL0~BTLn-1. Each of the memory cells MCs may include a cell transistor coupled to each of the word-lines WL0~WLm-1 and each of the bit-lines BTL0~BTLn-1 and a cell capacitor coupled to the cell transistor. Each of the memory cells MCs may have a DRAM cell structure. Each of the word-lines WL0~WLm-1 extends in a first direction DR1 and each of the bit-lines BTL1~BTLn-1 extends in a second direction DR2 crossing the first direction DR1.

The word-lines WL0~WLm-1 coupled to the plurality of memory cells MCs may be referred to as rows of the first bank array 710a and the bit-lines BTL0~BTLn-1 coupled to the plurality of memory cells MCs may be referred to as columns of the first bank array 710a.

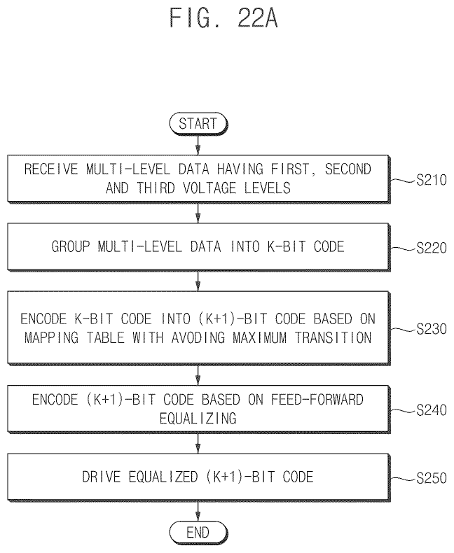

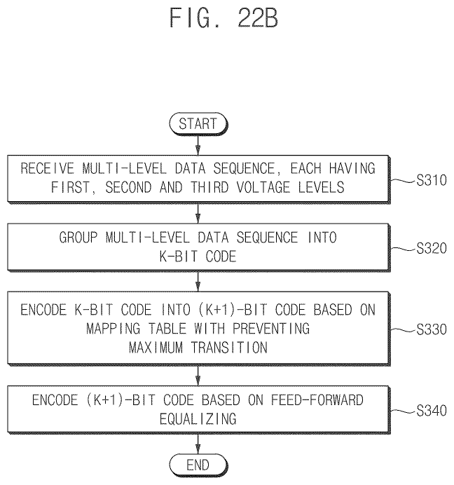

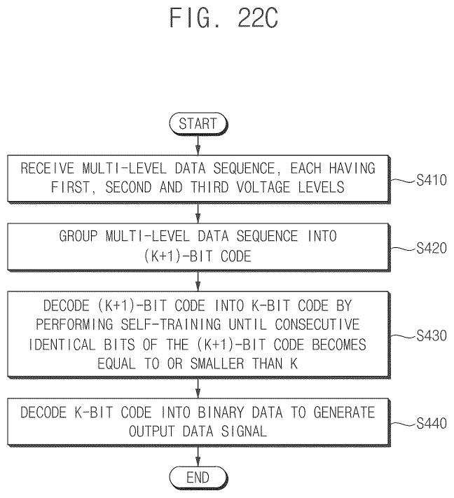

FIG. 22A is a flow chart illustrating an operation of a transmitter according to example implementations.

Referring to FIGS. 1 through 11 and 22A, the second encoder 150 may receive the first multi-level data MLDa and the second multi-level data MLDb which have a first voltage level, a second voltage level and a third voltage level (operation S210). The second encoder 150 may group each of the first multi-level data MLDa and the second multi-level data MLDb into a K-bit code T3 (K is a three) (operation S220) and may encode the grouped K-bit code T3 to (K+1)-bit code T4 based on a mapping table MT with avoiding a maximum transition of the (K+1)-bit code T4 (operation S230).

The third encoder 200 may generate control codes for controlling a crosstalk by encoding the (K+1)-bit code T4 based on a feed-forward equalization (operation S240). The driver 320 may generate the output data signal TX_OUT by driving the equalized (K+1)-bit code T4 (operation S250).

Therefore, in a method of operating the transmitter according to example implementations, the K-bit code T3 is encoded to the (K+1)-bit code T4 based on a mapping table MT with avoiding a maximum transition of the (K+1)-bit code T4 and the control codes for controlling a crosstalk are generated based on a feed-forward equalizing. Accordingly, a crosstalk of the output data signal TX_OUT may be cancelled and a data dependent jitter of the output data signal TX_OUT may be reduced.

FIG. 22B is a flow chart illustrating an encoding operation of a transmitter according to example implementations.

Referring to FIGS. 1 through 11 and 22B, the second encoder 150 may receive a multi-level data sequence that has a first voltage level, a second voltage level and a third voltage level (operation S310). The second encoder 150 may group the multi-level data sequence into a K-bit code T3 (K is a three) (operation S320) and may encode the grouped K-bit code T3 to (K+1)-bit code T4 based on a mapping table MT with avoiding a maximum transition of the (K+1)-bit code T4 (operation S330). The driver 320 may generate the output data signal TX_OUT by driving the (K+1)-bit code T4 (operation S340).

FIG. 22C is a flow chart illustrating a decoding operation of a receiver according to example implementations.

Referring to FIGS. 14 through 18 and 22C, the receiver 400 may receive a multi-level data sequence that has a first voltage level, a second voltage level and a third voltage level (operation S410). The first decoder 460 of the receiver 400 may group the multi-level data sequence into (K+1)-bit code T4 (operation S420). The first decoder 460 may decode the (K+1)-bit code T4 to a K-bit code T3 by performing a self training until a number of consecutive identical bits of the (K+1)-bit code T4[3:0] becomes equal to or smaller than K (operation S430). The second decoder 470 of the receiver 400 may generate the output data signal by decoding the K-bit code T3 into a binary data (operation S440).

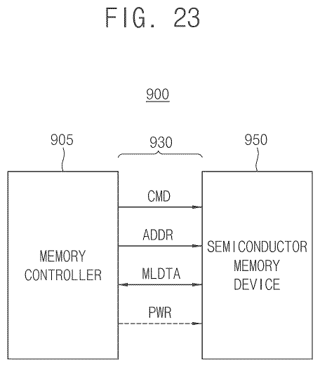

FIG. 23 is a block diagram illustrating a memory system according to example implementations.

Referring to FIG. 23, a memory system 900 may include a memory controller 905 and a semiconductor memory device 850. The memory system 900 may further include a plurality of signal lines 930 that electrically connect the memory controller 905 with the semiconductor memory device 950.

The semiconductor memory device 950 may be controlled by the memory controller 905. For example, based on requests from a host (not illustrated), the memory controller 905 may store (e.g., write or program) data into the semiconductor memory device 950, or may retrieve (e.g., read or sense) data from the semiconductor memory device 950.

The plurality of signal lines 930 may include control lines, command lines, address lines, data input/output (I/O) lines and power lines. The memory controller 905 may transmit a command CMD, an address ADDR and a control signal CTRL to the semiconductor memory device 950 via the command lines, the address lines and the control lines, may exchange a data signal MLDTA with the semiconductor memory device 950 via the data I/O lines, and may transmit a power supply voltage PWR to the semiconductor memory device 950 via the power lines.

For example, a data signal MLDTA may be a PAM-3 multi-level signal that is generated and transmitted according to example implementations. Although not illustrated in FIG. 23, the plurality of signal lines 930 may further include data strobe signal (DQS) lines for transmitting a DQS signal.

In some example implementations, at least a part or all of the signal lines 930 may be referred to as a channel. The term “channel” as used herein may represent signal lines that include the data I/O lines for transmitting the data signal MLDTA. However, example implementations are not limited thereto, and the channel may further include the command lines for transmitting the command CMD and/or the address lines for transmitting the address ADDR.

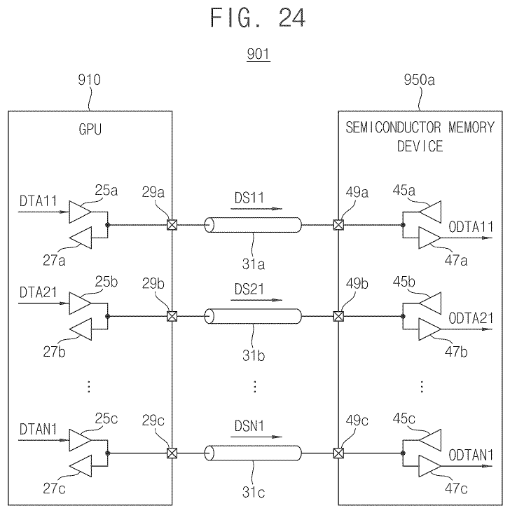

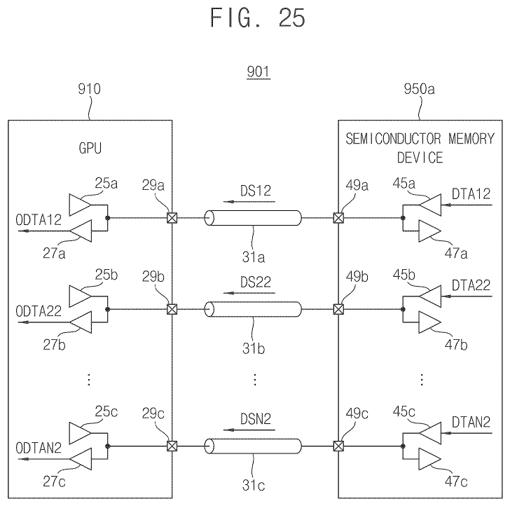

FIGS. 24 and 25 are block diagrams illustrating an example of a memory system of FIG. 23.

Referring to FIGS. 24 and 25, a memory system 901 may include a graphic processing unit (GPU) 910, a semiconductor memory device 950a and a plurality of channels 31a, 31b and 31c.

The GPU 910 may include a plurality of transmitters 25a, 25b and 25c, a plurality of receivers 27a, 27b and 27c, and a plurality of data I/O pads 29a, 29b and 29c. The semiconductor memory device 950a may include a plurality of transmitters 45a, 45b and 45c, a plurality of receivers 47a, 47b and 47c, and a plurality of data I/O pads 49a, 49b and 49c.

Each of the plurality of transmitters 25a, 25b, 25c, 45a, 45b and 45c may generate a PAM-3 multi-level signal, may perform the method of generating multi-level signal. Each of the plurality of receivers 27a, 27b, 27c, 47a, 47b and 47c may receive the PAM-3 multi-level signal. The plurality of transmitters 25a, 25b, 25c, 45a, 45b and 45c and the plurality of receivers 27a, 27b, 27c, 47a, 47b and 47c may transmit and receive PAM-3 multi-level signal through the plurality of channels 31a, 31b and 31c.

Each of the plurality of transmitters 25a, 25b, 25c, 45a, 45b and 45c may employ the transmitter 100 of FIG. 5 an each of the plurality of receivers 27a, 27b, 27c, 47a, 47b and 47c may employ the receiver 400 of FIG. 14.

Each of the plurality of data I/O pads 29a, 29b, 29c, 49a, 49b and 49c may be connected to a respective one of the plurality of transmitters 25a, 25b, 25c, 45a, 45b and 45c and a respective one of the plurality of receivers 27a, 27b, 27c, 47a, 47b and 47c.

The plurality of channels 31a, 31b and 31c may connect GUP 910 with the semiconductor memory device 950a. Each of the plurality of channels 31a, 31b and 31c may be connected to a respective one of the plurality of transmitters 25a, 25b and 25c and a respective one of the plurality of receivers 27a, 27b and 27c through a respective one of the plurality of data I/O pads 29a, 29b and 29c. In addition, each of the plurality of channels 31a, 31b and 31c may be connected to a respective one of the plurality of transmitters 45a, 45b and 45c and a respective one of the plurality of receivers 47a, 47b and 47c through a respective one of the plurality of data I/O pads 49a, 49b and 49c. The PAM-3 multi-level signal may be transmitted through each of the plurality of channels 31a, 31b and 31c.

FIG. 24 illustrates an operation of transferring data from the GPU 910 to the semiconductor memory device 950a. For example, the transmitter 25a may generate an output data signal DS11, which is the PAM-3 multi-level signal, based on input data DTA11, the output data signal DS11 may be transmitted from the GPU 910 to the semiconductor memory device 950a through the channel 31a, and the receiver 47a may receive the output data signal DS11 to obtain data ODTA11 corresponding to the input data DTA11.

Similarly, the transmitter 25b may generate an output data signal DS21, which is the PAM-3 multi-level signal, based on input data DTA21, the output data signal DS21 may be transmitted to the semiconductor memory device 950a through the channel 31b, and the receiver 47b may receive the output data signal DS21 to obtain data ODTA21 corresponding to the input data DTA21. The transmitter 25c may generate an output data signal DSN1, which is the PAM-3 multi-level signal, based on input data DTAN1, the output data signal DSN1 may be transmitted to the semiconductor memory device 950a through the channel 31c, and the receiver 47c may receive the output data signal DSN1 to obtain data ODTAN1 corresponding to the input data DTAN1. For example, the input data DTA11, DTA21 and DTAN1 may be write data to be written into the semiconductor memory device 950a.

FIG. 25 illustrates an operation of transferring data from the semiconductor memory device 950a to the GPU 910. For example, the transmitter 45a may generate an output data signal DS12, which is the PAM-3 multi-level signal, based on input data DTA12, the output data signal DS12 may be transmitted from the semiconductor memory device 950a to the GPU 910 through the channel 31a, and the receiver 27a may receive the output data signal DS12 to obtain data ODTA12 corresponding to the input data DTA12.

Similarly, the transmitter 45b may generate an output data signal DS22, which is the PAM-3 multi-level signal, based on input data DTA22, the output data signal DS22 may be transmitted to the GPU 910 through the channel 31b, and the receiver 27b may receive the output data signal DS22 to obtain data ODTA22 corresponding to the input data DTA22. The transmitter 45c may generate an output data signal DSN2, which is the PAM-3 multi-level signal, based on input data DTAN2, the output data signal DSN2 may be transmitted to GPU 910 through the channel 31c, and the receiver 27c may receive the output data signal DSN2 to obtain data ODTAN2 corresponding to the input data DTAN2. For example, the input data DTA12, DTA22 and DTAN2 may be read data retrieved from the semiconductor memory device 950a.

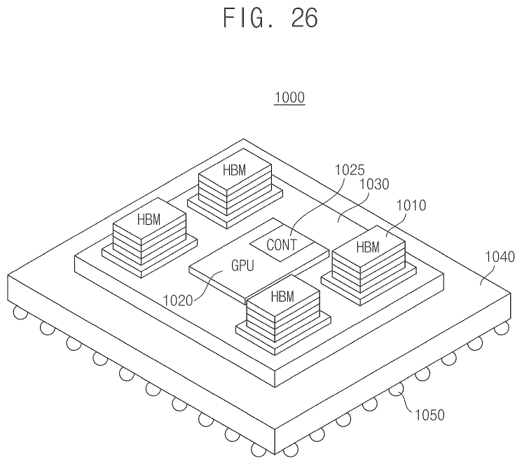

FIG. 26 is a diagram illustrating a semiconductor package including the stacked memory device according to example implementations.

Referring to FIG. 26, a semiconductor package 1000 may include one or more stacked memory devices 1010 and a GPU 1020 and the GPU 1020 includes a memory controller (CONT) 1025.

The stacked memory devices 1010 and the GPU 1020 may be mounted on an interposer 1030, and the interposer 1030 on which the stacked memory devices 1010 and the GPU 1020 are mounted may be mounted on a package substrate 1040. The package substrate 1040 may be mounted on solder balls 1050. The memory controller 1025 may employ the memory controller 520 in FIG. 2.

Each of the stacked memory devices 1010 may be implemented in various forms, and may be a memory device in a high bandwidth memory (HBM) form in which a plurality of layers are stacked. Accordingly, each of the stacked memory devices 1010 may include a buffer die and a plurality of memory dies, each of the plurality of memory dies may include a cell core, a cell core ECC engine and the buffer die may include a transmitter and a receiver.

The plurality of stacked memory devices 1010 may be mounted on the interposer 1030, and the GPU 1020 may communicate with the plurality of stacked memory devices 1010. For example, each of the stacked memory devices 1010 and the GPU 1020 may include a physical region, and communication may be performed between the stacked memory devices 1010 and the GPU 1020 through the physical regions.

The present disclosure may be applied to various electronic devices and systems that include the memory devices and the memory systems. For example, the present disclosure may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

The foregoing is illustrative of example implementations and is not to be construed as limiting thereof. Although a few example implementations have been described, those skilled in the art will readily appreciate that many modifications are possible in the example implementations without materially departing from the novel teachings and advantages of the present disclosure. Accordingly, all such modifications are intended to be included within the scope of the present disclosure as defined in the claims.

What is claimed is:

1. A transmitter comprising:
a first encoder configured to encode one or more pseudo random binary sequences to multi-level data, each level in the multi-level data indicating one voltage level of a plurality of voltage levels comprising at least a first voltage level, a second voltage level and a third voltage level;
a second encoder configured to group the multi-level data into a K-bit code and encode the K-bit code into (K+1)-bit code based on a mapping table, wherein a value of each bit of the (K+1)-bit code corresponds to a voltage level of the plurality of voltage levels, and K is three,
wherein a difference in values between any two consecutive bits of the (K+1)-bit code is less than a difference between highest and lowest values that each bit in the (K+1)-bit code can have;
a serializer configured to generate a first serial data and a second serial data based on the (K+1)-bit code; and
a driver configured to
generate an output data signal based on the first serial data, the second serial data, a pull-up control code, and a pull-down control code, and
transmit the output data signal through a channel.

2. The transmitter of claim 1, wherein the second encoder is configured to generate the (K+1)-bit code such that any two consecutive bits of the (K+1)-bit code transition by at most one voltage level.

3. The transmitter of claim 2, wherein the mapping table is configured to indicate a mapping relation between the K-bit code and the (K+1)-bit code, based on most significant two bits of the K-bit code, a least significant bit (LSB) of the K-bit code and a most significant bit (MSB) of a previous (K+1)-bit code.

4. The transmitter of claim 1, comprising:
a third encoder configured to
detect a transition of data on at least one adjacent channel,
generate, based on detection of the transition, a first control code and a second control code for cancelling crosstalk generated by the transition of the data, and
generate a first encoded data and a second encoded data based on the (K+1)-bit code;
a first pulse generator configured to generate the pull-up control code based on a first serial code; and
a second pulse generator configured to generate the pull-down control code based on a second serial code, and
wherein the third encoder is configured to adjust a number of bits of each of the first control code and the second control code based on a number of the at least one adjacent channel.

5. The transmitter of claim 4, wherein the third encoder is configured to generate a cancellation signal having a phase difference of 180 degrees with respect to a phase of the crosstalk based on the detected transition of the data, the first control code and the second control code.

6. The transmitter of claim 4, wherein the first pulse generator comprises:
a first AND gate configured to perform an AND operation on a first bit of the first serial code and a first clock signal;
a first buffer configured to output a first signal by buffering an output of the first AND gate;
a first inverter configured to generate a second signal by inverting the first signal;
a second AND gate configured to generate a first bit of the pull-up control code by performing an AND operation on the first signal and the second signal;
a third AND gate configured to perform an AND operation on a second bit of the first serial code and an inverted version of the first clock signal;
a second buffer configured to output a third signal by buffering an output of the third AND gate;
a second inverter configured to generate a fourth signal by inverting the third signal; and
a fourth AND gate configured to generate a second bit of the pull-up control code by performing an AND operation on the third signal and the fourth signal.

7. The transmitter of claim 6, wherein,
each of the first buffer and the second buffer has a first delay time interval that is variable, and
each of the first inverter and the second inverter has a second delay time interval that is variable.

8. The transmitter of claim 7, wherein the first bit of the pull-up control code is a pulse signal that is activated during the second delay time interval.

9. The transmitter of claim 4, comprising:
a serializer configured to:
generate the first serial code based on serializing of the first control code;
generate the second serial code based on serializing of the second control code;
generate the first serial data based on serializing of the first encoded data; and
generate the second serial data based on serializing of the second encoded data, and
a clock distribution network configured to generate, based on a first clock signal, a second clock signal and a third clock signal.

10. The transmitter of claim 9, wherein:
the first pulse generator and the second pulse generator are configured to operate based on the first clock signal;
the serializer is configured to operate based on the second clock signal;
the first encoder, the second encoder and the third encoder are configured to operate based on the third clock signal;
a frequency of the second clock signal is smaller than a frequency of the first clock signal; and
a frequency of the third clock signal is smaller than a frequency of the second clock signal.

11. The transmitter of claim 1, wherein the driver comprises:
a strength adjusting circuit configured to compensate for nonlinearity of the output data signal by adjusting an amount of a current provided to an output node based on a first strength control code, a second strength control code, the first serial data and the second serial data; and
a driver circuit configured to generate the output data signal by controlling a voltage at the output node based on the pull-up control code, the pull-down control code, the first serial data and the second serial data.

12. The transmitter of claim 11, wherein the driver circuit comprises:
a first p-channel metal-oxide semiconductor (PMOS) transistor coupled between a power supply voltage and the output node, wherein a gate of the first PMOS transistor is configured to receive a first bit of the pull-up control code;
a second PMOS coupled between the power supply voltage and the output node in parallel with the first PMOS transistor, wherein a gate of the second PMOS transistor is configured to receive a second bit of the pull-up control code;
a third PMOS transistor coupled between the power supply voltage and a first node, wherein a gate of the third PMOS transistor is configured to receive an inverted version of the first serial data;
a fourth PMOS transistor coupled between the first node and the output node, wherein a gate of the fourth PMOS transistor is configured to receive the first bit of the pull-up control code;
a fifth PMOS transistor coupled between the first node and the output node in parallel with the fourth PMOS transistor, wherein a gate of the fifth PMOS transistor is configured to receive the second bit of the pull-up control code;
a first n-channel metal-oxide semiconductor (NMOS) transistor coupled between a ground voltage and the output node, wherein a gate of the first NMOS transistor is configured to receive a first bit of the pull-down control code;
a second NMOS transistor coupled between the ground voltage and the output node in parallel with the first NMOS transistor, wherein a gate of the second NMOS transistor is configured to receive a second bit of the pull-down control code;
a third NMOS transistor coupled between a second node and the output node, wherein a gate of the third NMOS transistor is configured to receive the first bit of the pull-down control code;
a fourth NMOS transistor coupled between the second node and the output node in parallel with the third NMOS transistor, wherein a gate of the fourth NMOS transistor is configured to receive the second bit of the pull-down control code; and
a fifth NMOS transistor coupled between the ground voltage and the second node, wherein a gate of the fifth NMOS transistor is configured to receive the second serial data.

13. The transmitter of claim 12, wherein the third PMOS transistor, the fourth PMOS transistor, the fifth PMOS transistor, the third NMOS transistor, the fourth NMOS transistor and the fifth NMOS transistor form an asymmetric feed-forward equalizer.

14. A receiver comprising:
an amplifier configured to amplify an input data signal into an amplified signal, wherein the input data signal comprises a first voltage level, a second voltage level and a third voltage level, and wherein the input data signal is received through a channel;
a signal converter configured to convert the amplified signal into a differential signal comprising a first signal and a second signal;
a first comparator configured to sample the first signal to generate a first comparison signal;
a second comparator configured to sample the second signal to generate a second comparison signal;
a first decoder configured to group each of a first deserialized signal and a second deserialized signal into a (K+1)-bit code and generate, based on a number of consecutive identical bits of the (K+1)-bit code being equal to or smaller than K, a first decoded signal and a second decoded signal, wherein the first decoder is configured to decode the (K+1)-bit code into K-bit code based on a mapping table, and K is three; and
a second decoder configured to decode the first decoded signal and the second decoded signal to pseudo random binary sequences, based on a voltage level of each of the first decoded signal and the second decoded signal.

15. The receiver of claim 14, wherein, based on the number of consecutive identical bits of the (K+1)-bit code being greater than K, the first decoder is configured to perform a self-training operation by shifting the (K+1)-bit code until the number of consecutive identical bits of the (K+1)-bit code becomes equal to or smaller than K.

16. The receiver of claim 14, wherein the first decoder is configured to map the (K+1)-bit code to the K-bit code based on a most significant bit (MSB) of a previous (K+1)-bit code.

17. The receiver of claim 14, wherein the signal converter comprises:
a first resistor coupled between a power supply voltage and a first node;
a second resistor coupled between the power supply voltage and a second node;
a first n-channel metal-oxide semiconductor (NMOS) transistor coupled between the first node and a third node, wherein a gate of the first NMOS transistor is configured to receive the amplified signal;
a second NMOS transistor coupled between the second node and the third node, wherein a gate of the second NMOS transistor is configured to receive a reference voltage;
a third NMOS transistor coupled between the third node and a ground voltage, wherein a gate of the third NMOS transistor is configured to receive a bias voltage;
a third resistor coupled between the power supply voltage and a fourth node;
a fourth resistor coupled between the power supply voltage and a fifth node;
a fourth NMOS transistor coupled between the fourth node and a sixth node and has a gate connected to a fifth resistor coupled to the first node;
a fifth NMOS transistor coupled between the fifth node and the sixth node and has a gate connected to a sixth resistor coupled to the second node; and
a sixth NMOS transistor coupled between the sixth node and the ground voltage, wherein a gate of the sixth NMOS transistor is configured to receive the bias voltage, and
wherein the first signal is provided at the fourth node and the second signal is provided at the fifth node.

18. The receiver of claim 14, comprising:
a pseudo random binary sequence checker configured to selectively generate an error signal by checking the pseudo random binary sequences;
a deserializer configured to
deserialize the first comparison signal to generate the first deserialized signal, and
deserialize the second comparison signal to generate the second deserialized signal; and
a clock distribution network configured to generate, based on a first clock signal, a multi-phase clock signal, a second clock signal, a third clock signal and a fourth clock signal.

19. The receiver of claim 18, wherein:
the first comparator and the second comparator are configured to operate based on the multi-phase clock signal;
the deserializer is configured to operate based on the second clock signal;
the first decoder and the second decoder are configured to operate based on the third clock signal;
the pseudo random binary sequence checker is configured to operate the fourth clock signal;
a frequency of the second clock signal is smaller than a frequency of the first clock signal;
a frequency of the third clock signal is smaller than a frequency of the second clock signal; and
a frequency of the fourth clock signal is smaller than a frequency of the third clock signal.

20. A system comprising:
a transmitter configured to output a write data to be stored in a semiconductor memory device;
a channel configured to transmit the write data; and
a receiver configured to receive the write data,
wherein the transmitter is configured to:
group an input data signal into a K-bit code, the input data signal having a first voltage level, a second voltage level and a third voltage level;
encode the K-bit code into a (K+1)-bit code based on a mapping table, wherein a difference in values between any two consecutive bits of the (K+1)-bit code is less than a difference between highest and lowest values that each bit in the (K+1)-bit code can have, and K is three; and
generate the write data based on the (K+1)-bit code, and
wherein the receiver configured to:
convert the write data into a differential signal including a first signal and a second signal;
sample the first signal and the second signal to generate a first comparison signal and a second comparison signal, respectively;
group each of a first deserialized signal and a second deserialized signal into the (K+1)-bit code and generate, in response to a number of consecutive identical bits of the (K+1)-bit code being equal to or smaller than K, a first decoded signal and a second decoded signal by decoding the (K+1)-bit code into the K-bit code; and
generate a data signal based on the first decoded signal and the second decoded signal.
